(19) United States
(12) Patent Application Publication
(10) Pub. No.: US 2025/0318371 A1
(43) Pub. Date: Oct. 9, 2025

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Fei FANG, Beijing (CN); Changchang LIU, Beijing (CN); Hongting LU, Beijing (CN); Ling SHI, Beijing (CN); Bo PENG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/859,279

(22) PCT Filed: Nov. 13, 2023
(86) PCT No.: PCT/CN2023/131284

§ 371 Date: Oct. 23, 2024

(30) Foreign Application Priority Data
Dec. 26, 2022 (CN) 202211676069.7

(51) Int. Cl. H10K 59/131; H10K 59/121; H10K 59/65

(52) U.S. Cl. CPC H10K 59/131; H10K 59/1213; H10K 59/1216; H10K 59/65

(57) ABSTRACT

A display panel includes a primary display region and a secondary display region. A light transmittance of the primary display region is less than a light transmittance of the secondary display region. The display panel includes first pixel circuits located in the secondary display region. The first pixel circuits are arranged in rows and columns. The display panel includes a substrate, a first conductive layer and a first signal line layer. The first pixel circuits include conductive patterns located in the first conductive layer. The first signal line layer includes first-type signal lines extending in a first direction. A conductive pattern of each first pixel circuit located in a same row in the first direction is electrically connected to a first-type signal line through a first via hole, and the first via hole is located on a side of the first pixel circuit in the first direction.

### CROSS-REFERENCE TO RELATED APPLICATIONS

This application is a national phase entry under 35 USC 371 of International Patent Application No. PCT/CN2023/131284, filed on Nov. 13, 2023, which claims priority to Chinese Patent Application No. 202211676069.7, filed on Dec. 26, 2022, each are incorporated herein by reference in their entirety.

### TECHNICAL FIELD

The present disclosure relates to the field of display technologies, and in particular, to a display panel and a display apparatus.

### BACKGROUND

With the development of display technology, full display with camera (abbreviated as FDC) has been gradually applied to display products due to its advantage of a large screen-to-body ratio. In a full-screen display apparatus, an optical component such as a camera is usually placed in a region under a display panel, thereby greatly increasing the screen-to-body ratio.

### SUMMARY

In an aspect, a display panel is provided. The display panel includes a primary display region and a secondary display region, the primary display region surrounds at least a part of the secondary display region, and a light transmittance of the primary display region is less than a light transmittance of the secondary display region. The display panel includes a plurality of first pixel circuits located in the secondary display region, the plurality of first pixel circuits are arranged in a plurality of rows and a plurality of columns, first pixel circuits in each row are arranged in a first direction, and first pixel circuits in each column are arranged in a second direction, the first direction and the second direction intersecting. The display panel includes: a substrate, a first conductive layer located on the substrate, the plurality of first pixel circuits including conductive patterns located in the first conductive layer; and a first signal line layer located on a side of the first conductive layer away from the substrate and located in the secondary display region, the first signal line layer including first-type signal lines extending in the first direction. A conductive pattern of each first pixel circuit located in a same row in the first direction is electrically connected to a first-type signal line through a first via hole, and the first via hole is located on a side of the first pixel circuit in the first direction.

In some embodiments, each of the first pixel circuits is electrically connected to a first-type signal line through a first via hole; and first via holes of different first pixel circuits are each located on a same side of a respective first pixel circuit.

In some embodiments, the first conductive layer is a first gate conductive layer, the conductive pattern is a gate pattern, and the first signal line layer is a first light-transmitting conductive layer.

In some embodiments, the first gate conductive layer includes a first via hole connection portion electrically connected to the gate pattern; the first via hole exposes the first via hole connection portion; the gate pattern is electrically connected to the first-type signal line through the first via hole connection portion; and the first via hole connection portion is located on a side outside a region occupied by the first pixel circuit, or is located within the region occupied by the first pixel circuit.

In some embodiments, the first pixel circuit includes a plurality of gate patterns; the plurality of gate patterns are arranged in a plurality of columns in the first direction, and are arranged in a plurality of rows in the second direction; a same row of gate patterns includes at least two gate patterns; and the at least two gate patterns are electrically connected to a same first-type signal line through a same first via hole connection portion.

In some embodiments, the at least two gate patterns are of a one-piece structure; and/or the at least two gate patterns and the first via hole connection portion electrically connected to the at least two gate patterns are of a one-piece structure.

In some embodiments, the first-type signal lines include at least one of gate lines, reset signal lines, or enable signal lines.

In some embodiments, the first-type signal line in the secondary display region is located in a same layer and is a continuous line; and an orthographic projection of the first-type signal line on the substrate overlaps with an orthographic projection of at least one first pixel circuit among the plurality of first pixel circuits on the substrate.

In some embodiments, the display panel further includes a plurality of second pixel circuits located in the primary display region; the first gate conductive layer further includes second-type signal lines located in the primary display region; the second-type signal lines extend in the first direction and are electrically connected to at least some second pixel circuits among the plurality of second pixel circuits; a first-type signal line and a second-type signal line that transmit a same electrical signal are electrically connected to each other.

In some embodiments, the display panel further includes: a semiconductor layer located on a side of the first conductive layer close to the substrate, and a second light-transmitting conductive layer that is located on a side of the first light-transmitting conductive layer away from the substrate and located in the secondary display region; the second light-transmitting conductive layer includes: fourth-type signal lines extending in the second direction; the first pixel circuit further includes a third active pattern located in the semiconductor layer; a third active pattern of each first pixel circuit in a same column is electrically connected to a fourth-type signal line through a third via hole, and the third via hole is located on a side of the first pixel circuit in the second direction.

In some embodiments, each of the first pixel circuits is electrically connected to a fourth-type signal line through a third via hole; and third via holes of different first pixel circuits are each located on a same side of a respective first pixel circuit.

In some embodiments, the fourth-type signal line in the secondary display region is located in a same layer and is a continuous line; and an orthographic projection of the fourth-type signal line on the substrate overlaps with an orthographic projection of at least one first pixel circuit among the plurality of first pixel circuits on the substrate.

In some embodiments, the semiconductor layer includes a third via hole connection portion electrically connected to the third active pattern; the third via hole exposes the third via hole connection portion; the third active pattern is electrically connected to the fourth-type signal line through the third via hole connection portion; the third via hole connection portion is located on a side outside a region occupied by the first pixel circuit, or is located within the region occupied by the first pixel circuit.

In some embodiments, the fourth-type signal lines include data signal lines.

In some embodiments, the display panel further includes: a second source-drain conductive layer located on a side of the second light-transmitting conductive layer away from the substrate; the second source-drain conductive layer includes a plurality of fifth-type signal lines located in the primary display region; the plurality of fifth-type signal lines extend in the second direction, and are electrically connected to at least some second pixel circuits among the plurality of second pixel circuits; a fifth-type signal line is electrically connected to the fourth-type signal line.

In some embodiments, the display panel further includes: a second gate conductive layer located on a side of the first gate conductive layer away from the substrate; the first pixel circuit includes a capacitor pattern located in the second gate conductive layer; the first pixel circuit further includes a fourth active pattern located in the semiconductor layer; the second light-transmitting conductive layer further includes third connection lines; in the second direction, a third connection line is located between two adjacent first pixel circuits; a fourth active pattern of one of the two adjacent first pixel circuits is electrically connected to an end of the third connection line through a fourth via hole; a capacitor pattern of another one of the two adjacent first pixel circuits is electrically connected to another end of the third connection line through another fourth via hole.

In some embodiments, the display panel further includes: a second source-drain conductive layer located on a side of the second light-transmitting conductive layer away from the substrate; the second source-drain conductive layer includes fourth connection lines located in the secondary display region; in the second direction, a fourth connection line is located between two adjacent third connection lines and connects the two adjacent third connection lines.

In some embodiments, in the second direction, a plurality of third connection lines and a plurality of fourth connection lines are alternately arranged and sequentially connected, and are configured to transmit a first voltage signal.

In some embodiments, the display panel further includes a plurality of second pixel circuits located in the primary display region; within a unit area, an area occupied by the plurality of second pixel circuits is greater than an area occupied by the plurality of first pixel circuits.

In another aspect, a display apparatus is provided. The display apparatus includes: the display panel as described in any of the above embodiments, and an optical component located on a non-light exit side of the display panel and located in the secondary display region of the display panel.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings to be described below may be regarded as schematic diagrams, and are not limitations on actual sizes of products involved in the embodiments of the present disclosure.

FIG. 1 is a structural diagram of a display apparatus, in accordance with some embodiments of the present disclosure;

FIG. 2 is a structural diagram of a display panel, in accordance with some embodiments of the present disclosure;

FIG. 3 is a structural diagram of a pixel circuit, in accordance with some embodiments of the present disclosure;

FIG. 4a is a structural diagram of another display panel, in accordance with some embodiments of the present disclosure;

FIG. 4b is a structural diagram of yet another display panel, in accordance with some embodiments of the present disclosure;

FIG. 5 is a structural diagram of another display apparatus, in accordance with some embodiments of the present disclosure;

FIG. 6 is a top view showing structures of some film layers of a display panel, in accordance with some embodiments of the present disclosure;

FIG. 7 is a top view showing structures of some other film layers of a display panel, in accordance with some embodiments of the present disclosure;

FIG. 8 is a structural diagram of yet another display panel, in accordance with some embodiments of the present disclosure;

FIG. 9a is a top view showing structures of some film layers of a display panel, in accordance with an implementation;

FIG. 9b is a sectional view showing structures of some film layers of a display panel, in accordance with an implementation;

FIG. 10a is a top view showing structures of some film layers of a display panel, in accordance with some embodiments of the present disclosure;

FIG. 10b is a top view showing structures of some other film layers of a display panel, in accordance with some embodiments of the present disclosure;

FIG. 10c is a top view showing structures of yet some other film layers of a display panel, in accordance with some embodiments of the present disclosure;

FIG. 10d is a top view showing structures of yet some other film layers of a display panel, in accordance with some embodiments of the present disclosure;

FIG. 11 is a top view showing structures of yet some other film layers of a display panel, in accordance with some embodiments of the present disclosure;

FIG. 12 is a top view showing structures of yet some other film layers of a display panel, in accordance with some embodiments of the present disclosure;

FIG. 13 is a top view showing structures of yet some other film layers of a display panel, in accordance with some embodiments of the present disclosure;

FIG. 14 is a top view showing structures of yet some other film layers of a display panel, in accordance with some embodiments of the present disclosure;

FIG. 15 is a top view showing structures of yet some other film layers of a display panel, in accordance with some embodiments of the present disclosure;

FIG. 16 is a top view showing structures of yet some other film layers of a display panel, in accordance with some embodiments of the present disclosure;

FIG. 17 is a top view showing structures of yet some other film layers of a display panel, in accordance with some embodiments of the present disclosure;

FIG. 18 is a top view showing structures of yet some other film layers of a display panel, in accordance with some embodiments of the present disclosure;

FIG. 19 is a top view showing structures of yet some other film layers of a display panel, in accordance with some embodiments of the present disclosure;

FIG. 20 is a top view showing structures of yet some other film layers of a display panel, in accordance with some embodiments of the present disclosure;

FIG. 21 is a schematic diagram showing a connection between a third-type signal line and an initial signal line in a display panel, in accordance with some embodiments of the present disclosure;

FIG. 22 is a schematic diagram showing a connection between a first-type signal line and a second-type signal line in a display panel, in accordance with some embodiments of the present disclosure;

FIG. 23 is a top view showing structures of yet some other film layers of a display panel, in accordance with some embodiments of the present disclosure;

FIG. 24 is a top view showing structures of yet some other film layers of a display panel, in accordance with some embodiments of the present disclosure;

FIG. 25 is a top view showing structures of yet some other film layers of a display panel, in accordance with some embodiments of the present disclosure;

FIG. 26 is a schematic diagram showing a connection between a fourth-type signal line and a fifth-type signal line in a display panel, in accordance with some embodiments of the present disclosure;

FIG. 27 is a top view showing structures of yet some other film layers of a display panel, in accordance with some embodiments of the present disclosure;

FIG. 28 is a top view showing structures of yet some other film layers of a display panel, in accordance with some embodiments of the present disclosure;

FIG. 29 is a top view showing structures of yet some other film layers of a display panel, in accordance with some embodiments of the present disclosure;

FIG. 30 is a top view showing structures of yet some other film layers of a display panel, in accordance with some embodiments of the present disclosure;

FIG. 31 is a top view showing structures of yet some other film layers of a display panel, in accordance with some embodiments of the present disclosure;

FIG. 32 is a top view showing structures of yet some other film layers of a display panel, in accordance with some embodiments of the present disclosure;

FIG. 33 is a top view showing structures of yet some other film layers of a display panel, in accordance with some embodiments of the present disclosure; and

FIG. 34 is a top view showing structures of yet some other film layers of a display panel, in accordance with some embodiments of the present disclosure.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “the plurality of” means two or more unless otherwise specified.

In the description of some embodiments, the term “connected” and its derivatives may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. For example, the term “connected” may be used in the description of some embodiments to indicate that two or more components are in direct physical or electrical contact with each other. The embodiments disclosed herein are not necessarily limited to the content herein.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

The term such as “about”, “substantially” or “approximately” as used herein includes a stated value and an average value within an acceptable range of deviation of a particular value determined by a person of ordinary skilled in the art, considering measurement in question and errors associated with measurement of a particular quantity (i.e., limitations of a measurement system).

The term such as “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “perpendicular” includes absolute perpendicularity and approximate perpendicularity, and an acceptable range of deviation of the approximate perpendicularity may be a deviation within 5°; and the term “equal” includes absolute equality and approximate equality, and an acceptable range of deviation of the approximate equality may be a difference between two equals being less than or equal to 5% of either of the two equals.

It will be understood that, in a case where a layer or component is referred to as being on another layer or a substrate, it may be that the layer or component is directly on the another layer or substrate; or it may be that intermediate layer(s) exist between the layer or component and the another layer or substrate.

Exemplary embodiments are described herein with reference to sectional views and/or plan views as idealized exemplary drawings. In the drawings, thicknesses of layers and sizes of regions are enlarged for clarity. Thus, variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

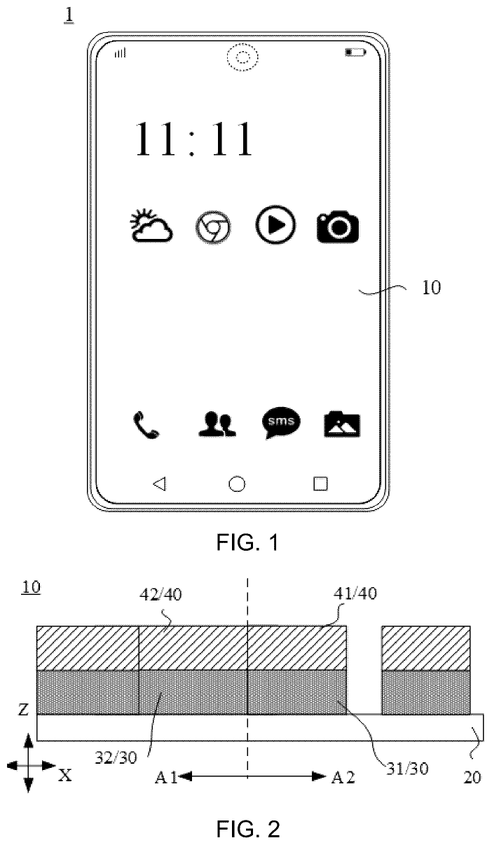

As shown in FIG. 1, some embodiments of the present disclosure provide a display apparatus 1. The display apparatus 1 may be any apparatus that displays an image whether in motion (such as a video) or stationary (such as a still image), and whether textual or graphical. More specifically, it is expected that the display apparatus in the embodiments may be implemented in or associated with a plurality of electronic devices. The plurality of electronic devices may include (but are not limit to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (such as odometer displays), navigators, cockpit controllers and/or displays, camera view displays (such as rear view camera displays in vehicles), electronic photos, electronic billboards or indicators, projectors, building structures, packagings and aesthetic structures (such as displays for an image of a piece of jewelry), etc.

In some examples, the display apparatus 1 may be an organic light-emitting diode (OLED) display apparatus.

For example, the display apparatus 1 includes a frame, a display driver integrated circuit (IC) and other electronic components.

In some examples, as shown in FIG. 1, the display apparatus 1 further includes a display panel 10.

For example, as shown in FIG. 2, the display panel 10 includes a substrate 20, a plurality of pixel circuits 30 disposed on the substrate 20, and a plurality of light-emitting devices 40 disposed on a side of the pixel circuits 30 away from the substrate 20.

In FIG. 2, a Z direction is a thickness direction of the substrate 20.

For example, the substrate 20 may be a flexible substrate, or may be a rigid substrate.

For example, when the substrate 20 is a flexible substrate, the substrate 20 may be made of a material with high elasticity such as dimethylsiloxane, polyimide (PI), or polyethylene terephthalate (PET).

As another example, when the substrate 20 is a rigid substrate, the substrate 20 may be made of glass.

In some examples, the plurality of pixel circuits 30 are electrically connected to the plurality of light-emitting devices 40, respectively.

For example, the plurality of pixel circuits 30 and the plurality of light-emitting devices 40 may be electrically connected in one-to-one correspondence. As another example, a single pixel circuit 30 may be coupled to multiple light-emitting devices 40; alternatively, multiple pixel circuits 30 may be coupled to a single light-emitting device 40.

The structure of the display panel 10 in the present disclosure will be described below by considering an example in which a single pixel circuit 30 is electrically connected to a single light-emitting device 40.

For example, in the display panel 10, each light-emitting device 40 may emit light under drive of a corresponding pixel circuit 30, and light emitted by the plurality of light-emitting devices 40 cooperates such that the display panel 10 realizes the display function.

For example, the light-emitting device 40 may include an anode, a light-emitting functional layer and a cathode that are sequentially stacked. The light-emitting functional layer may include a light-emitting layer. Optionally, the light-emitting functional layer may further include at least one of a hole injection layer, a hole transport layer, an electron transport layer, or an electron injection layer.

By applying a common voltage to the cathode of the light-emitting device 40, and applying a driving signal to the anode of the light-emitting device 40 using the corresponding pixel circuit 30, an electric field may be created between the anode and the cathode. The electric field may drive carriers (i.e., holes and electrons) to recombine in the light-emitting layer, so that the light-emitting device 40 emits light.

In some examples, the structure of the pixel circuit 30 varies, which may be set according to actual needs. For example, the pixel circuit 30 may be of a “6T1C” structure, a “7T1C” structure, a “6T2C” structure, or a “7T2C” structure. Here, “T” represents a transistor, a number in front of “T” represents the number of transistors, “C” represents a storage capacitor, and a number in front of “C” represents the number of storage capacitors.

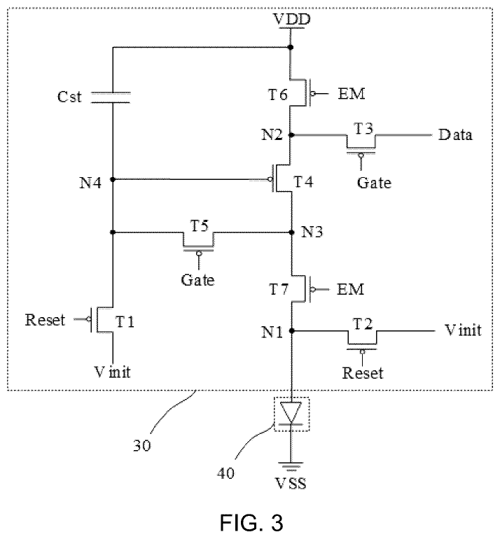

For example, the present disclosure will be described by considering an example in which the pixel circuit 30 is of a “7T1C” structure. FIG. 3 shows an equivalent circuit diagram of the pixel circuit 30.

It will be understood that, during the operation of the pixel circuit 30, signal lines are required to provide corresponding electrical signals for the pixel circuit 30.

For example, the display panel 10 further includes: a plurality of gate lines Gate, a plurality of data lines Data, a plurality of reset signal lines Reset, a plurality of first voltage signal lines VDD, a plurality of initial signal lines Vinit, and a plurality of enable signal lines EM. The gate lines Gate are used to transmit scan signals, the data lines Data are used to transmit data signals, the reset signal lines Reset are used to transmit reset signals, the first voltage signal lines VDD are used to transmit first voltage signals, the initial signal lines Vinit are used to transmit initial signals, and the enable signal lines EM are used to transmit enable signals.

For example, the plurality of gate lines Gate, the plurality of reset signal lines Reset, the plurality of initial signal lines Vinit, and the plurality of enable signal lines EM may extend in a first direction X; and the plurality of first voltage signal lines VDD and the plurality of data lines Data may extend in a second direction Y. For example, the first direction X and the second direction Y are perpendicular to each other.

For example, the display panel 10 further includes: a plurality of second voltage signal lines VSS, and the second voltage signal lines VSS are used to transmit second voltage signals. The second voltage signals are, for example, common voltage signals.

For example, as shown in FIG. 3, the pixel circuit 30 includes a first reset transistor T1, a second reset transistor T2, a switching transistor T3, a driving transistor T4, a compensation transistor T5, a first light-emitting control transistor T6, a second light-emitting control transistor T7, and a storage capacitor Cst.

For example, as shown in FIG. 3, a gate of the first reset transistor T1 is electrically connected to a reset signal line Reset, a first electrode of the first reset transistor T1 is electrically connected to an initial signal line Vinit, and a second electrode of the first reset transistor T1 is electrically connected to a fourth node N4 (i.e., electrically connected to a second electrode of the compensation transistor T5). The first reset transistor T1 is configured to be turned on under control of the reset signal transmitted by the reset signal line Reset and transmit the initial signal received at the initial signal line Vinit to the fourth node N4, so as to reset the fourth node N4.

For example, as shown in FIG. 3, a gate of the second reset transistor T2 is electrically connected to the reset signal line Reset, a first electrode of the second reset transistor T2 is electrically connected to the initial signal line Vinit, and a second electrode of the second reset transistor T2 is electrically connected to a first node N1 (i.e., electrically connected to the light-emitting device 40). The second reset transistor T2 is configured to be turned on under control of the reset signal transmitted by the reset signal line Reset and transmit the initial signal received at the initial signal line Vinit to the first node N1, so as to reset the first node N1.

For example, as shown in FIG. 3, a gate of the switching transistor T3 is electrically connected to a gate line Gate, a first electrode of the switching transistor T3 is electrically connected to a data line Data, and a second electrode of the switching transistor T3 is electrically connected to a second node N2 (i.e., electrically connected to a first electrode of the driving transistor T4). The switching transistor T3 is configured to be turned on under control of the scan signal transmitted by the gate line Gate and transmit the data signal received at the data line Data to the second node N2.

For example, as shown in FIG. 3, a gate of the driving transistor T4 is electrically connected to the fourth node N4, the first electrode of the driving transistor T4 is electrically connected to the second node N2, and a second electrode of the driving transistor T4 is electrically connected to a third node N3. The driving transistor T4 is configured to be turned on under control of a voltage of the fourth node N4 and transmit a signal (e.g., the data signal) from the second node N2 to the third node N3.

For example, as shown in FIG. 3, a gate of the compensation transistor T5 is electrically connected to the gate line Gate, a first electrode of compensation transistor T5 is electrically connected to the third node N3 (i.e., electrically connected to the second electrode of the driving transistor T4), and a second electrode of the compensation transistor T5 is electrically connected to the fourth node N4 (i.e., electrically connected to the gate of driving transistor T4). The compensation transistor T5 is configured to be turned on under the control of the scan signal transmitted by the gate line Gate and transmit an electrical signal (e.g., the data signal) from the third node N3 to the fourth node N4.

For example, as shown in FIG. 3, a gate of the first light-emitting control transistor T6 is electrically connected to an enable signal line EM, a first electrode of the first light-emitting control transistor T6 is electrically connected to a first voltage signal line VDD, and a second electrode of the first light-emitting control transistor T6 is electrically connected to the second node N2. The first light-emitting control transistor T6 is configured to be turned on under control of the enable signal transmitted by the enable signal line EM and transmit the voltage signal received at the first voltage signal line VDD to the second node N2.

For example, as shown in FIG. 3, a gate of the second light-emitting control transistor T7 is electrically connected to the enable signal line EM, a first electrode of the second light-emitting control transistor T7 is electrically connected to the third node N3, and a second electrode of the second light-emitting control transistor T7 is electrically connected to the first node N1. The second light-emitting control transistor T7 is configured to be turned on under the control of the enable signal transmitted by the enable signal line EM and transmit an electrical signal (e.g., the voltage signal) from the third node N3 to the first node N1.

For example, as shown in FIG. 3, a second electrode (also called a second electrode plate) of the storage capacitor Cst is electrically connected to the fourth node N4, and a first electrode (also called a first electrode plate) of the storage capacitor Cst is electrically connected to the first voltage signal line VDD.

For example, the operation process of the pixel circuit 30 includes a reset phase, a data writing and compensation phase, and a light-emitting phase in sequence.

For example, in the reset phase, the first reset transistor T1 is turned on under the control of the reset signal and transmits the initial signal to the fourth node N4, so as to reset the fourth node N4. Since the fourth node N4 is electrically connected to the first electrode of the storage capacitor Cst, the gate of the driving transistor T4, and the second electrode of the compensation transistor T5, when the fourth node N4 is reset, the first electrode of the storage capacitor Cst, the gate of the driving transistor T4, and the second electrode of the compensation transistor T5 may be reset at the same time. The driving transistor T4 may be turned on under the control of the initial signal. Next, the second reset transistor T2 is turned on under the control of the reset signal, and the second reset transistor T2 transmits the initial signal to the first node N1, so as to reset the first node N1. Since the first node N1 is electrically connected to the anode of the light-emitting device 40, when the first node N1 is reset, the anode of the light-emitting device 40 may be reset at the same time.

For example, in the data writing and compensation phase, the switching transistor T3 is turned on under the control of the scan signal, and the compensation transistor T5 is turned on under the control of the scan signal. The switching transistor T3 transmits the data signal to the second node N2. The driving transistor T4 transmits the data signal from the second node N2 to the third node N3. The compensation transistor T5 transmits the data signal from the third node N3 to the fourth node N4, so as to charge the driving transistor T4 until the compensation of the threshold voltage of the driving transistor T4 is completed.

For example, in the light-emitting phase, the first light-emitting control transistor T6 and the second light-emitting control transistor T7 are both turned on under the control of the enable signal. The first light-emitting control transistor T6 transmits the voltage signal to the second node N2. The driving transistor T4 transmits the voltage signal from the second node N2 to the third node N3. The second light-emitting control transistor T7 transmits the voltage signal from the third node N3 to the first node N1.

The light-emitting device 40 emits light due to the voltage signal from the first node N1 as well as the second voltage signal from the second voltage signal line VSS.

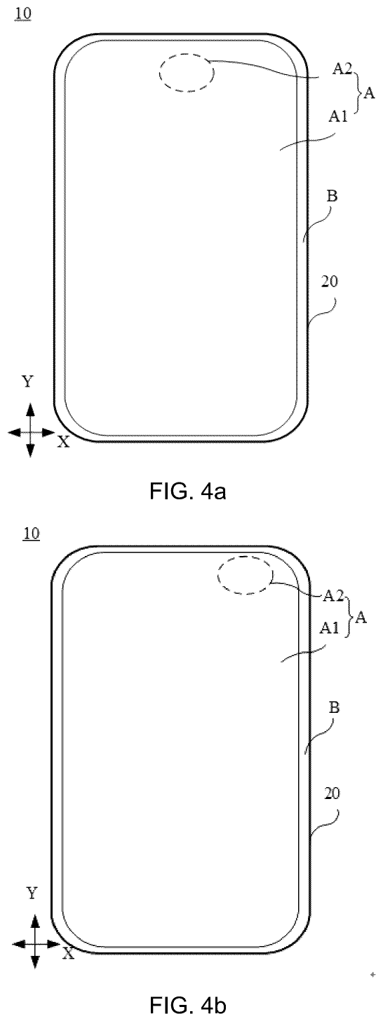

In some embodiments, as shown in FIGS. 4a and 4b, the display panel 10 has a display region A and a peripheral region B.

For example, the peripheral region B may be located on a periphery of the display region A. The peripheral region B may be used for an arrangement of shift registers, so as to provide required electrical signals for the display region A.

For example, the display region A includes a primary display region A1 and a secondary display region A2, and the primary display region A1 surrounds at least part of the secondary display region A2.

For example, as shown in FIG. 4a, in the first direction X, the secondary display region A2 may be located in a middle of the primary display region A1. Alternatively, as shown in FIG. 4b, in the first direction X, the secondary display region A2 may be located on a side of the primary display region A1.

For example, a part of the display panel 10 located in the primary display region A1 and a part of the display panel 10 located in the secondary display region A2 may both be used for displaying an image.

For example, the light transmittance of the primary display region A1 is less than the light transmittance of the secondary display region A2.

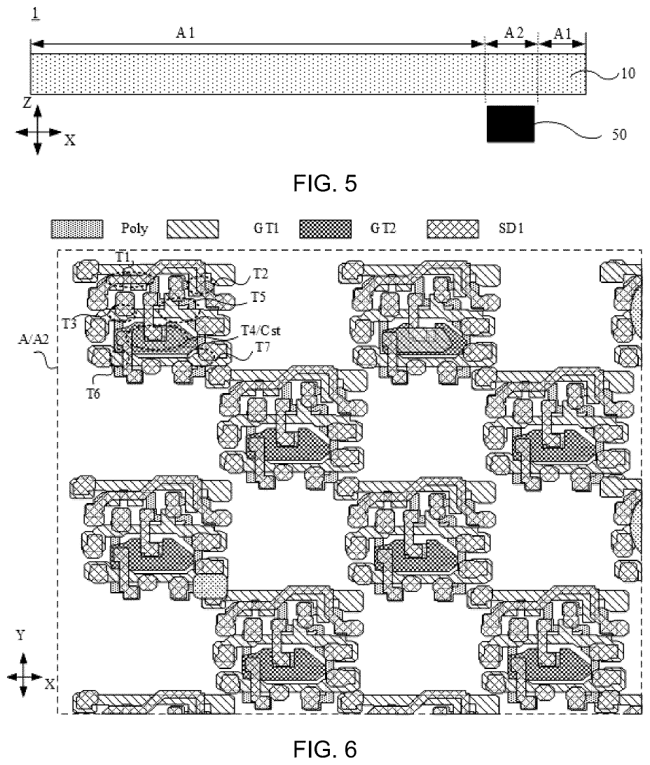

In some examples, as shown in FIG. 5, the display apparatus 1 further includes an optical component 50 that is disposed on a non-light exit side of the display panel 10 and located in the secondary display region A2 of the display panel 10.

For example, a light exit side of the display panel 10 refers to a side of the display panel 10 for displaying an image, and the non-light exit side of the display panel 10 refers to a side opposite to the light exit side.

In some examples, the optical component 50 is located in the secondary display region A2. In this way, external light may pass through the part of the display panel 10 located in the secondary display region A2, be incident on the optical component 50, and be collected by the optical component 50. Therefore, the optical component 50 can operate normally.

For example, the optical component 50 may be a camera, a fingerprint recognition sensor, an infrared sensor, etc.

The embodiments of the present disclosure is described by taking an example in which the optical component 50 is a camera.

For example, during the operation process of the camera, the external light may pass through the part of the display panel 10 located in the secondary display region A2. In this way, the camera may collect the light to realize a photographing function. For example, when the camera is operating (e.g., a user is taking a selfie), a black image may be displayed in the secondary display region A2, and a selfie image of the user may be displayed in the primary display region A1, which clearly shows the location of the camera. Alternatively, the primary display region A1 and the secondary display region A2 together display a selfie image of the user, without showing the location of the camera.

For example, when the camera is not operating, the part of the display panel 10 located in the primary display region A1 and the part of the display panel 10 located in the secondary display region A2 can both display images, so that the entire display panel 10 and the entire display apparatus 1 can display images.

For example, when the secondary display region A2 displays images, the optical component 50 may also operate.

By setting the light transmittance of the part of the display panel 10 located in the secondary display region A2 and providing the optical component 50 in the secondary display region A2, it may be possible to ensure that the optical component 50 can operate normally and increase a display area of the display panel 10 and the display apparatus 1, and in turn increase the screen-to-body ratio.

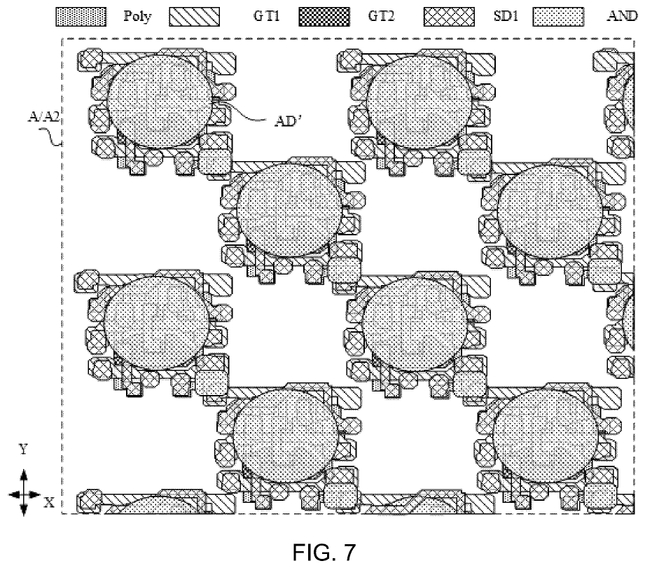

In some examples, as shown in FIGS. 6 and 7, the display panel 10 includes a semiconductor layer Poly, a first gate conductive layer GT1, a second gate conductive layer GT2, a first source-drain conductive layer SD1 and an anode layer AND that are sequentially stacked on a side of the substrate 20.

Of course, the display panel 10 may further include a second source-drain conductive layer disposed between the first source-drain conductive layer SD1 and the anode layer AND.

For example, a first insulating layer may be provided between the semiconductor layer Poly and the first gate conductive layer GT1, a second insulating layer may be provided between the first gate conductive layer GT1 and the second gate conductive layer GT2, an interlayer dielectric layer may be provided between the second gate conductive layer GT2 and the first source-drain conductive layer, a planarization layer may be provided between the first source-drain conductive layer SD1 and the second source-drain conductive layer, and a passivation layer may be provided between the second source-drain conductive layer and the anode layer AND.

For example, the first insulating layer GI1 and the second insulating layer GI2 may be made of silicon oxide, silicon nitride, and silicon oxynitride.

For example, the passivation layer may be made of an insulating material such as silicon oxide, silicon nitride or silicon oxynitride.

In order to facilitate the identification of pattern structures of other film layers, the first insulating layer, the second insulating layer, the interlayer dielectric layer, the passivation layer, etc. are not illustrated.

For example, a material of the semiconductor layer Poly may include amorphous silicon, monocrystalline silicon, polycrystalline silicon, or a metal oxide semiconductor material.

For example, the first gate conductive layer GT1, the second gate conductive layer GT2, the first source-drain conductive layer SD1 and the second source-drain conductive layer may each be made of a conductive material. The first gate conductive layer GT1 and the second gate conductive layer GT2 may be, for example, made of the same material. The first source-drain conductive layer SD1 and the second source-drain conductive layer may be, for example, made of the same material.

For example, the first gate conductive layer GT1, the second gate conductive layer GT2, the first source-drain conductive layer SD1 or the second source-drain conductive layer may be made of a metal material, which may be any or a combination of aluminum (Al), silver (Ag), copper (Cu), chromium (Cr), molybdenum (Mo), or titanium (Ti) or the like.

It will be noted that an orthographic projection of the semiconductor layer Poly on the substrate 20 overlaps with an orthographic projection of the first gate conductive layer GT1 on the substrate. After the first gate conductive layer GT1 is formed on a side of the semiconductor layer Poly away from the substrate, the semiconductor layer Poly may be doped using the first gate conductive layer GT1 as a mask. Therefore, portions of the semiconductor layer Poly covered by the first gate conductive layer GT1 form active patterns (e.g., channel regions) of the transistors, and portions of the semiconductor layer Poly not covered by the first gate conductive layer GT1 form conductors, and the conductors may serve as first electrodes or second electrodes of the transistors. Portions of the first gate conductive layer GT1 overlapping the semiconductor layer Poly form gate patterns (i.e., gates) of the transistors.

It will be understood that the first source-drain conductive layer SD1, the second source-drain conductive layer SD2, the semiconductor layer Poly, the first gate conductive layer GT1, and the second gate conductive layer GT2 form the plurality of pixel circuits 30.

For example, the relative positional relationship between each transistor and the storage capacitor included in the pixel circuit 30 is shown in FIG. 6. The first light-emitting control transistor T6 and the second light-emitting control transistor T7 are arranged in sequence in the first direction X. The first reset transistor T1, the switching transistor T3 and the first light-emitting control transistor T6 are arranged in sequence in the second direction Y. The second reset transistor T2 and the second light-emitting control transistor T7 are arranged in sequence in the second direction Y.

A plane perpendicular to the substrate 20 of the display panel 10 and along the first direction X is set as a first reference plane. An orthographic projection of the driving transistor T4 on the first reference plane is located between orthographic projections of the compensation transistor T5 and the switching transistor T3 on the first reference plane. A plane perpendicular to the substrate 20 of the display panel 10 and along the second direction Y is set as a second reference plane. An orthographic projection of the driving transistor T4 on the second reference plane is located between orthographic projections of the switching transistor T3 and the first light-emitting control transistor T6 on the second reference plane.

In the second direction Y, the second reset transistor T2 is also located on a side of the driving transistor T4 away from the second light-emitting control transistor T7. The location of the storage capacitor Cst is the same as the location of the driving transistor T4.

In this way, the arrangement of the pixel circuits 30 may be more regular, which facilitates the manufacturing of the display panel 10.

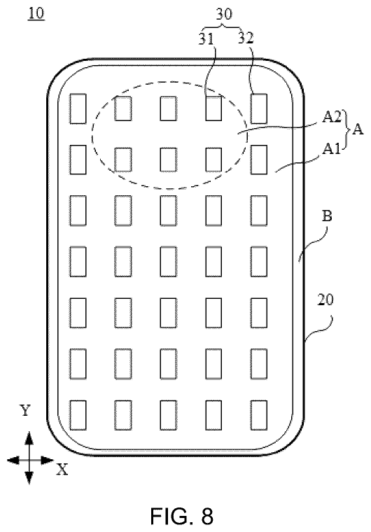

In some examples, as shown in FIG. 8, the display panel 10 includes a plurality of first pixel circuits 31 located in the secondary display region A2, the plurality of first pixel circuits 31 are arranged in a plurality of rows and a plurality of columns, first pixel circuits 31 in each row are arranged in the first direction X, and first pixel circuits 31 in each column are arranged in the second direction Y. The display panel 10 further includes a plurality of second pixel circuits 32 located in the primary display region A1, the plurality of second pixel circuits 32 are arranged in a plurality of rows and a plurality of columns, second pixel circuits 32 in each row are arranged in the first direction X, and second pixel circuits 32 in each column are arranged in the second direction Y.

It will be understood that, the structure of each of the first pixel circuit 31 and the second pixel circuit 32 may be the above-mentioned “7T1C” structure.

For example, the first direction X and the second direction Y intersect.

For example, an angle between the first direction X and the second direction Y is 85°, 90°, 95°, etc.

For the convenience of description, the embodiments of the present disclosure will be introduced by taking an example in which the angle between the first direction X and the second direction Y is 90°.

For example, the plurality of first pixel circuits 31 and the plurality of second pixel circuits 32 are arranged in an array.

For example, a row of pixel circuits 30 may all be first pixel circuits 31.

As another example, among multiple pixel circuits in a row of pixel circuits 30, a part of pixel circuits may be first pixel circuits 31, and another part of pixel circuits may be second pixel circuits 32.

For example, there is a gap between two adjacent first pixel circuits 31. The external light may be incident on the optical component 50 through the gap. Therefore, the optical component 50 may collect sufficient light to realize a photographing function.

For example, as shown in FIG. 2, the plurality of light-emitting devices 40 include a plurality of first light-emitting devices 41 and a plurality of second light-emitting devices 42.

For example, the plurality of second light-emitting devices 42 are located in the primary display region A1, and the plurality of first light-emitting devices 41 are located in the secondary display region A2.

For example, the plurality of first light-emitting devices 41 are electrically connected to the plurality of first pixel circuits 31, and the plurality of second light-emitting devices 42 are electrically connected to the plurality of second pixel circuits 32.

In order to improve the light transmittance of the secondary display region, as shown in FIG. 7, an anode AD′ of a first light-emitting device is generally arranged to cover a first pixel circuit electrically connected thereto. Due to the limitation of the fabricating process of the pixel circuit, the first pixel circuit cannot be completely hidden under the corresponding anode AD′. When the external light is incident on the optical component through the gap between two adjacent first pixel circuits, the external light will be diffracted on the metal structures (such as the first gate conductive layer) in the first pixel circuits around the gap, which easily affects the optical component from collecting light, resulting in serious diffraction phenomenon in the optical component. Furthermore, the gap between two adjacent first pixel circuits is small, so that the light transmittance of the secondary display region is low, which affects the light collection amount of the optical component and in turn affects the function of the optical component.

In light of this, in some embodiments of the present disclosure, as shown in FIG. 8, within a unit area, an area occupied by a plurality of second pixel circuits 32 is set to be greater than an area occupied by a plurality of first pixel circuits 31. For example, the number of first pixel circuits 31 within a unit area is the same as the number of second pixel circuits 32 within a unit area, and an area occupied by a single second pixel circuit 32 is greater than an area occupied by a single first pixel circuit 31. The area of the pixel circuit located in the secondary display region A2 is compressed compared with the pixel circuit in the primary display region A1. Therefore, the gap between two adjacent first pixel circuits 31 is larger, and the light transmittance of the secondary display region A2 is improved. As a result, it may be possible to increase the light collection amount of the optical component 50, and in turn improve the photographic quality of the optical component 50. In addition, in this way, it may increase a proportion of an area of the first pixel circuit 31 hidden under the anode of the corresponding first light-emitting device to a total area of the first pixel circuit 31, and reduce a proportion of an area of the first pixel circuit 31 exposed outside the anode to the total area of the first pixel circuit 31, thereby reducing the probability of photographic diffraction during the process of external light being incident on the optical component 50, and effectively mitigating the phenomenon of photographic diffraction in the optical component.

In one implementation, as shown in FIG. 6, the display panel 10 further includes: a first light-transmitting conductive layer (not shown in FIG. 6) located on the first gate conductive layer GT1 and located in the secondary display region A2.

For example, the first light-transmitting conductive layer is located on a surface, away from the substrate, of the passivation layer on the first gate conductive layer GT1.

It will be understood that film layers stacked in sequence on a side of the first gate conductive layer GT1 away from the substrate may include the second insulating layer, the second gate conductive layer, the interlayer dielectric layer, the first source-drain conductive layer SD1, the passivation layer, and the first light-transmitting conductive layer.

A material of the first light-transmitting conductive layer has both light-transmitting and conductive properties.

For example, the first light-transmitting conductive layer TC1 may be made of indium tin oxide (ITO).

In some examples, the first pixel circuit 31 (see FIG. 8) includes gate patterns GP located in the first gate conductive layer GT1.

For example, the gate patterns GP form the gates of the transistors in the first pixel circuit 31. The gates of the transistors are connected to signal lines.

In another implementation, the gap between two adjacent first pixel circuits 31 in the secondary display region A2 is used for light transmission. A portion of a signal line (e.g., a gate line, reset signal line, enable signal line, etc. as mentioned above, which is electrically connected to the first pixel circuits in a row of first pixel circuits) that is located between two adjacent first pixel circuits may be composed of a connection line formed by a light-transmitting conductive material. The light-transmitting conductive connection line is used to realize the connection of the signal line between the first pixel circuits in a row, thereby increasing the transmittance of the secondary display region.

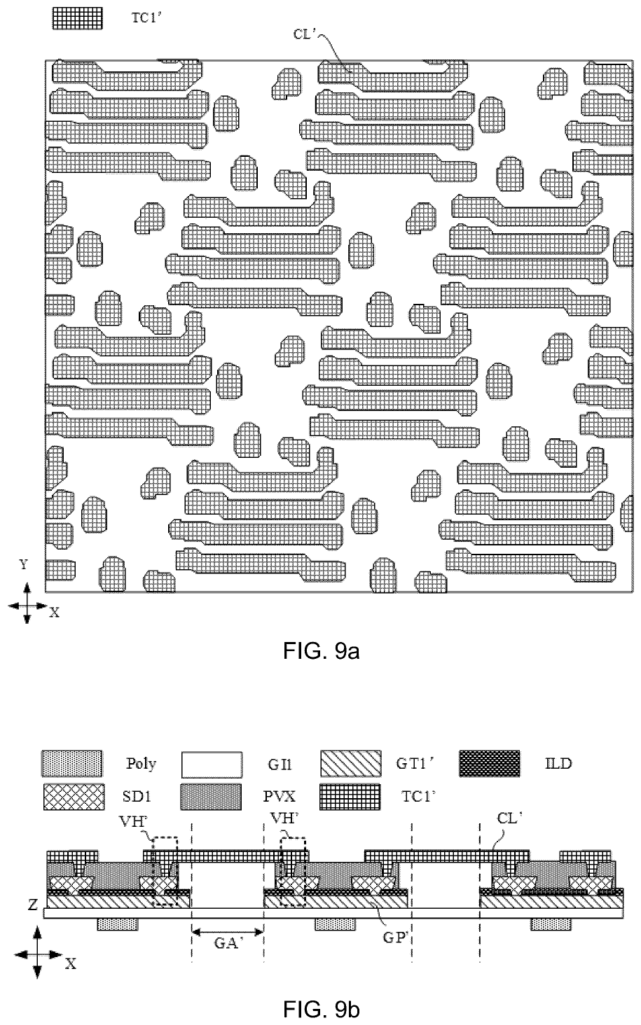

Considering an example in which the above-mentioned signal line is a gate line, the gate line is connected to gate pattern(s) of the pixel circuit. For example, as shown in FIG. 9a, the connection line CL′ may be provided in the first light-transmitting conductive layer TC1′. As shown in FIG. 9b, the gate line and the gate patterns of the first pixel circuit are located in the first gate conductive layer GT1′, and the connection line CL′ is located in the first light-transmitting conductive layer TC1′, so that the gate pattern GP′ and the connection line CL′ are located in different film layers, and the connection line CL′ needs to be electrically connected to the gate line and the gate pattern GP′ through via hole(s) (as shown in FIG. 9b, in order to facilitate the electrical connection between the gate pattern and the connection line, FIG. 9b only illustrates the passivation layer PVX between the first light-transmitting conductive layer TC1′ and the gate pattern GP′, and FIG. 9b is a sectional view taken along an extending direction of the gate line or the connection line CL′). Therefore, in a row of first pixel circuits, two sides of a region occupied by each first pixel circuit (for example, two opposite sides along a row direction of the first pixel circuit) each need to be provided with one via hole (that is, two via holes VH′ in total), to realize the gate line and the gate pattern GP′ being connected to the connection line CL′.

However, in this way, the number of via holes located in the secondary display region is large, which makes it easy for external light to be diffracted in the above multiple via holes when the external light is incident on the optical component, thereby affecting the light collection of the optical component, and making the optical component prone to adverse phenomena such as photographic diffraction. In addition, since the via hole VH′ occupies the area of the gap GA′ between two adjacent first pixel circuits, i.e., occupies the region in the secondary display region for the external light to enter and pass through, a light-transmitting area of the secondary display region is small and the light transmittance of the secondary display region is low. As a result, the amount of light collected by the optical component is small, which affects the function of the optical component. Considering a low temperature poly-silicon (LTPS) type pixel circuit as an example, when the pixel density is 400 pixels per inch (PPI), the light-transmitting area ratio of the secondary display region (or called an aperture ratio, which refers to a ratio of an area of the light-transmitting region to an area of the secondary display region A2) is approximately 48.3%.

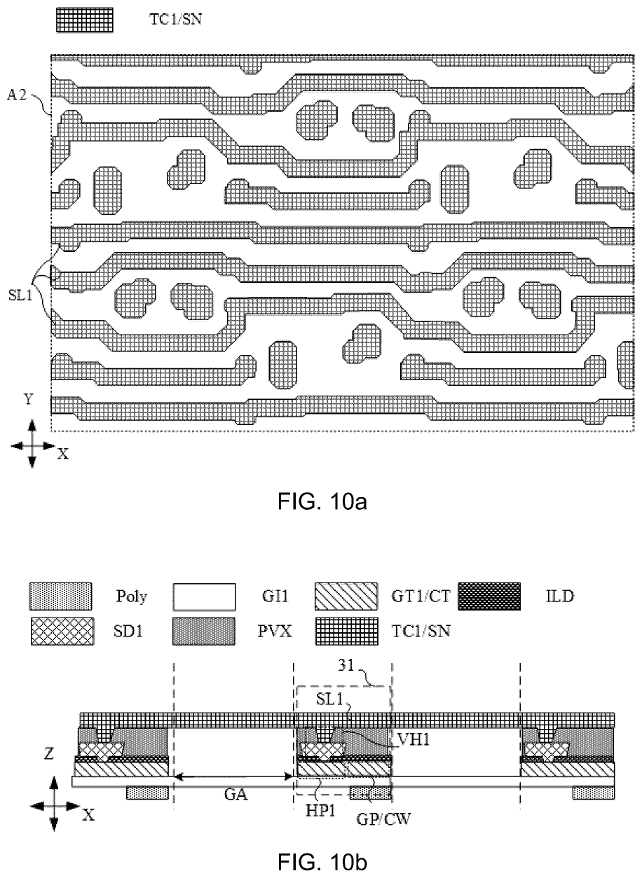

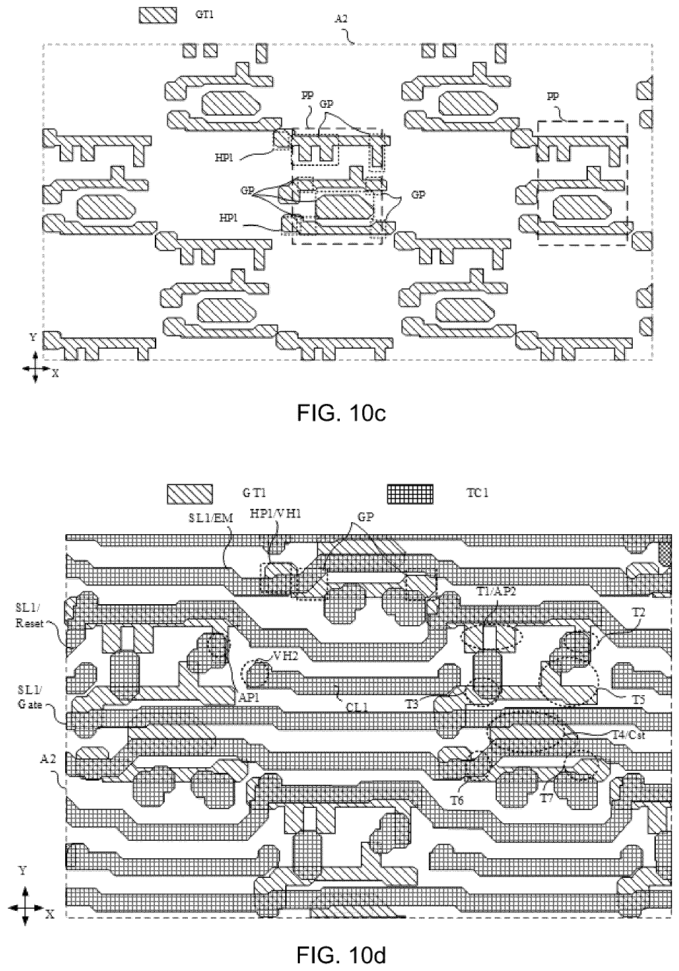

Some embodiments of the present disclosure provide a display panel 10. As shown in FIGS. 10a and 10b, the display panel 10 further includes: a first conductive layer CT located on the substrate, and the plurality of first pixel circuits 31 include conductive patterns CW located in the first conductive layer CT.

In some examples, the display panel 10 further includes: a first signal line layer SN located on a side of the first conductive layer CT away from the substrate and located in the secondary display region A2, and the first signal line layer SN includes first-type signal lines SL1 extending in the first direction X.

For example, the first-type signal lines SL1 are used for transmitting electrical signals.

In some examples, conductive patterns CW of first pixel circuits 31 in the same row in the first direction X are electrically connected to a first-type signal line SL1 through first via holes VH1, and a first via hole VH1 is located on a side of a first pixel circuit 31 in the first direction X.

For example, a first via hole VH1 corresponding to a conductive pattern CW of each first pixel circuit 31 is located on one of two opposite sides of a corresponding first pixel circuit 31 in the first direction X.

For example, as shown in FIG. 10b, the first via hole VH1 refers to a via hole penetrating through film layers (for example, the passivation layer PVX, the interlayer dielectric layer ILD, etc. in FIG. 10b) between the first signal line layer SN and the first conductive layer CT in order to realize the electrical connection between the conductive pattern CW and the first-type signal line SL1. Due to the limitation of the process of forming via holes and the thicknesses of the film layers, the first via hole VH1 may be composed of a plurality of sub-holes sequentially connected in the Z direction. The sub-holes are substantially concentrically arranged, or the sub-holes are staggered with each other. The sub-holes are located in different film layers, and a conductive transfer block is formed in each sub-hole. The conductive transfer block extends to an upper surface of a film layer where a corresponding sub-hole is located (for example, the conductive transfer block is formed by using the material of the first source-drain conductive layer SD1 in FIG. 10b), and each conductive transfer block passes through each sub-hole to realize the electrical connection between the conductive pattern CP and the first-type signal line SL1.

In some embodiments of the present disclosure, the first signal line layer SN is provided in the secondary display region A2; the first signal line layer SN includes first-type signal lines SL1; the first-type signal lines SL1 extend in the first direction X; the conductive pattern CW of the first pixel circuit 31 in the same row in the secondary display region A2 is electrically connected to the first-type signal line SL1 through a first via hole VH1; and the first via hole VH1 is located on a side of the first pixel circuit 31 in the first direction X. Therefore, the number of first via holes VH1 around or inside the region occupied by a single first pixel circuit 31 is small. Compared with the one implementation, the number of first via holes VH1 around or inside the region occupied by each first pixel circuit 31 is reduced, so that the number of via holes in the secondary display region A2 is reduced, which mitigates the diffraction phenomenon during the process of the external light entering the optical component 50 and avoids the photographic diffraction phenomenon of the optical component 50 to a certain extent. In addition, the number of the first via holes VH1 is reduced, which may result in a large gap GA between two adjacent first pixel circuits 31 in the secondary display region A2. That is, a region originally used to form the first via hole VH1 may be used as a region for the external light to enter and pass through, i.e., a light-transmitting region. Thus, the light-transmitting area in the secondary display region A2 is increased, the light transmittance of the secondary display region A2 is increased, and the light collection amount of the optical component 50 is guaranteed. Considering the LTPS type pixel circuit as an example, when the pixel density is 400 PPI, the light-transmitting area ratio of the secondary display region A2 (or called an aperture ratio, which refers to a ratio of an area of the light-transmitting region to an area of the secondary display region A2) is approximately 52.5%. The light-transmitting area ratio of the secondary display region A2 is increased by 4.2%, which significantly increases the light-transmitting area of the secondary display region A2 and mitigates the photographic diffraction phenomenon of the optical component.

In some embodiments, each first pixel circuit 31 is electrically connected to the first-type signal line SL1 through a first via hole VH1. It will be understood that the relative positional relationship between the first via hole VH1 and a corresponding first pixel circuit 31 varies, which may be set according to actual needs, which will not be limited in the present disclosure.

For example, in the same row of first pixel circuits 31, a first via hole VH1 corresponding to each first pixel circuit 31 may be located on a different side of the first pixel circuit 31 in the first direction X.

As another example, in the same row of first pixel circuits 31, first via holes VH1 corresponding to different first pixel circuits 31 are each located on a same side of a respective first pixel circuit 31.

In this way, the arrangement of the first via holes VH1 in the display panel may be more regular, thereby reducing the difficulty of manufacturing the display panel.

In some embodiments, the first conductive layer CT includes the first gate conductive layer GT1, the conductive pattern CP includes the gate pattern GP, and the first signal line layer SN includes the first light-transmitting conductive layer TC1.

For example, the material of the first light-transmitting conductive layer has both light-transmitting and conductive properties. The first light-transmitting conductive layer TC1 may be made of indium tin oxide (ITO).

For example, a single first-type signal line SL1 is electrically connected to a single row of first pixel circuits 31.

For example, a single first-type signal line SL1 is electrically connected to gate patterns GP of a corresponding row of first pixel circuits 31, and transmits an electrical signal to the corresponding row of first pixel circuits 31.

In some embodiments, as shown in FIGS. 10a and 10b, the first-type signal line SL1 is located in the same layer in the secondary display region A2 and is a continuous line, and an orthographic projection of the first-type signal line SL1 on the substrate overlaps with an orthographic projection of at least one first pixel circuit 31 among the plurality of first pixel circuits 31 on the substrate.

For example, the first-type signal line SL1 is formed by a strip pattern that is integral and unbroken and substantially in the first direction. The entire first-type signal lines SL1 is located in the same layer in the secondary display region, and is located in the first light-transmitting conductive layer TC1. Thus, it may simplify the process of manufacturing the display panel.

For example, a portion of a first-type signal line SL1 is located in a gap between two adjacent first pixel circuits 31, and another portion of the first-type signal line SL1 covers a portion of a corresponding first pixel circuit 31.

For example, an orthographic projection of a first-type signal line SL1 on the substrate 20 partially overlaps with an orthographic projection of each first pixel circuit 31 in a corresponding row of first pixel circuits 31 on the substrate 20.

In some embodiments, as shown in FIGS. 10b, 10c and 10d, the first gate conductive layer GT1 includes a first via hole connection portion HP1 electrically connected to a gate pattern GP, and a first via hole VH1 exposes the first via hole connection portion HP1. The gate pattern GP is electrically connected to the first-type signal line SL1 through the first via hole connection portion HP1.

For example, the first via hole connection portion HP1 and the gate pattern GP are arranged in the same layer and made of the same material.

For example, the first via hole VH1 may expose a portion of the first via hole connection portion HP1.

For example, the first via hole connection portion HP1 is located on a side outside a region occupied by the first pixel circuit 31 where the gate pattern GP connected to the first via hole connection portion HP1 is located; alternatively, the first via hole connection portion HP1 is located within the region occupied by the first pixel circuit 31 where the gate pattern GP connected to the first via hole connection portion HP1 is located.

In FIG. 10c, a region defined by the dotted box PP is the region occupied by the first pixel circuit 31.

For example, the first via hole connection portion HP1 is located in a surrounding region outside the region occupied by the first pixel circuit 31.

As another example, an orthographic projection of the first via hole connection portion HP1 on the substrate 20 is located within an orthographic projection of the first pixel circuit 31 on the substrate 20. Thus, it may be possible to reduce an area occupied by the first via hole of the light-transmitting region in the secondary display region A2, and in turn make the area of the light-transmitting region of the secondary display region A2 larger. As a result, it may be possible to increase the light transmittance of the secondary display region A2, increase the light collection amount of the optical component 50, and ensure the normal operation of the optical component 50.

For example, the first-type signal line SL1 may cover at least a portion of the corresponding first via hole VH1.

In this way, the gate pattern GP is electrically connected to the first-type signal line SL1 through a first via hole connection portion HP1, which may avoid a limitation of a relative position of an orthographic projection of the gate pattern GP on the substrate, and in turn avoid that the orthographic projection of the first-type signal line SL1 on the substrate needs to partially overlap with the orthographic projection of the gate pattern GP on the substrate, or avoid that the orthographic projection of the first-type signal line SL1 on the substrate needs to be located around the orthographic projection of the gate pattern GP on the substrate, so as to facilitate the electrical connection between the gate pattern GP and the first-type signal line SL1. In the case where there are a large number of first-type signal lines SL1 in the first light-transmitting conductive layer TC1, due to the above arrangement manner, it may be convenient to arrange the relative positions of the plurality of first-type signal lines SL1 in the first light-transmitting conductive layer TC1, and avoid interference between electrical signals on adjacent first-type signal lines SL1 due to a small spacing between adjacent first-type signal lines SL1. As a result, it may be possible to improve the accuracy of the electrical signals transmitted by the first-type signal lines SL1, and in turn improve the display quality of images displayed by the display panel 10.

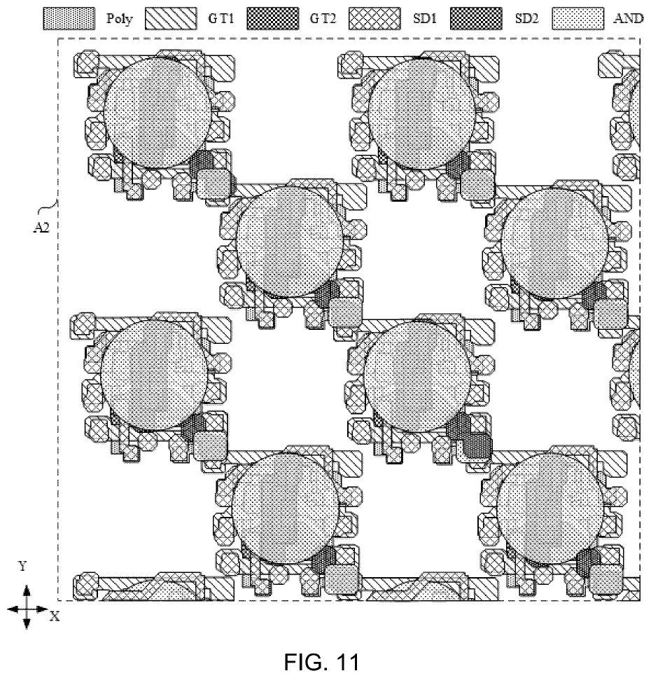

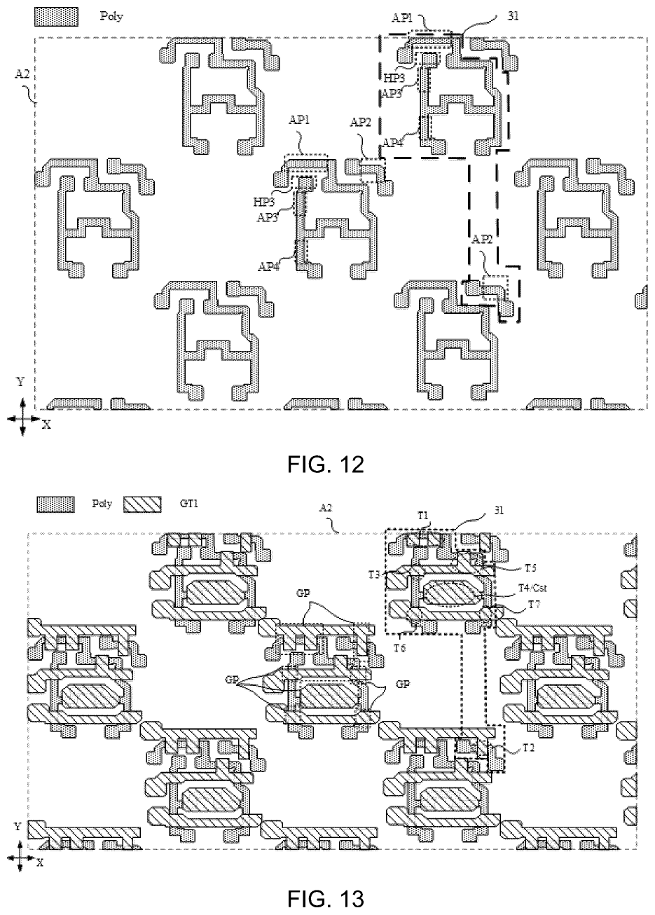

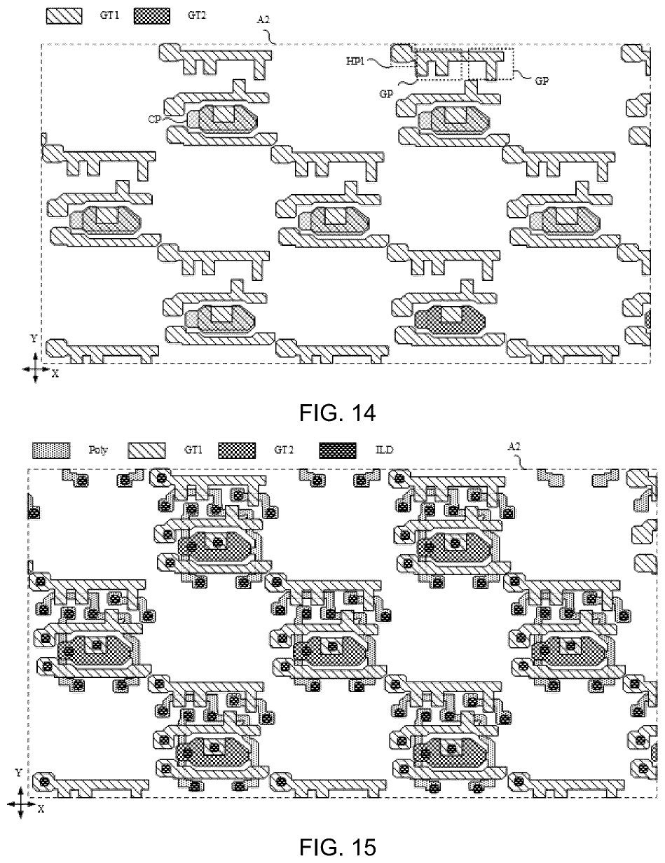

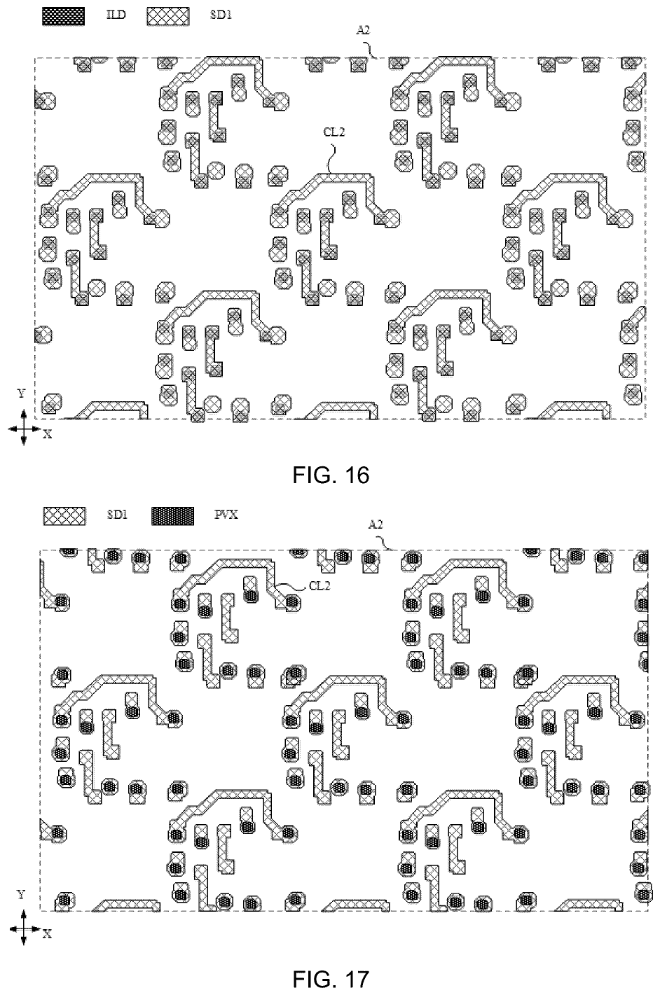

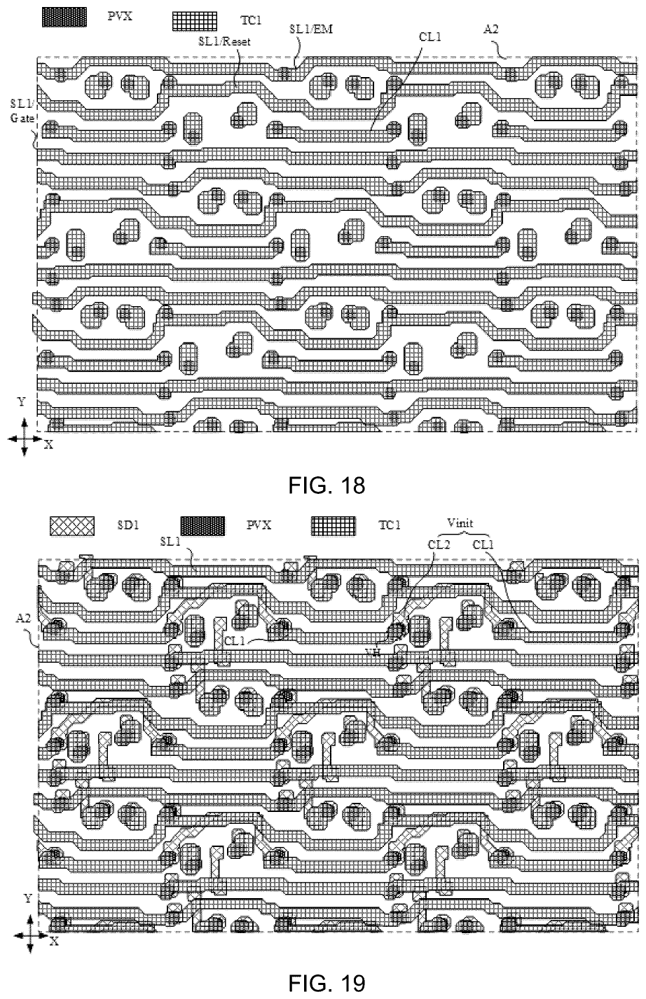

It will be understood that, FIG. 11 illustrates a top view of a structure where a semiconductor layer Poly, a first gate conductive layer GT1, a second gate conductive layer GT2, a first source-drain conductive layer SD1, a second source-drain conductive layer SD2 and a anode layer AND are sequentially stacked in a secondary display region A2. FIG. 12 illustrates a top view of a structure of a semiconductor layer Poly in a secondary display region A2. FIG. 13 illustrates a top view of a structure where a semiconductor layer Poly and a first gate conductive layer GT1 are sequentially stacked in a secondary display region A2. FIG. 14 illustrates a top view of a structure where a first gate conductive layer GT1 and a second gate conductive layer GT2 are sequentially stacked in a secondary display region A2. FIG. 15 illustrates a top view of a structure where a semiconductor layer Poly, a first gate conductive layer GT1, a second gate conductive layer GT2, and an interlayer dielectric layer ILD are sequentially stacked in a secondary display region A2 (only positions of via holes in the interlayer dielectric layer ILD in the secondary display region A2 are illustrated in FIG. 15). FIG. 16 illustrates a top view of a structure where an interlayer dielectric layer ILD and a first source-drain conductive layer SD1 are sequentially stacked in a secondary display region A2 (only positions of via holes in the interlayer dielectric layer ILD in the secondary display region A2 are illustrated in FIG. 16). FIG. 17 illustrates a top view of a structure where a first source-drain conductive layer SD1 and a passivation layer PVX are sequentially stacked in a secondary display region A2 (only positions of via holes in the passivation layer PVX in the secondary display region A2 are illustrated in FIG. 17). FIG. 18 illustrates a top view of a structure where a passivation layer PVX and a first light-transmitting conductive layer TC1 are sequentially stacked in a secondary display region A2 (only positions of via holes in the passivation layer PVX in the secondary display region A2 are illustrated in FIG. 18). FIG. 19 illustrates a top view of a structure where a first source-drain conductive layer SD1, a passivation layer PVX and a first light-transmitting conductive layer TC1 are sequentially stacked in a secondary display region A2 (only positions of via holes in the passivation layer PVX in the secondary display region A2 are illustrated in FIG. 19).

Of course, the semiconductor layer Poly is located on a side of the substrate. There may be other film layers between the substrate and the first light-transmitting conductive layer TC1, which may be set according to actual needs, which will not be limited in the present disclosure.

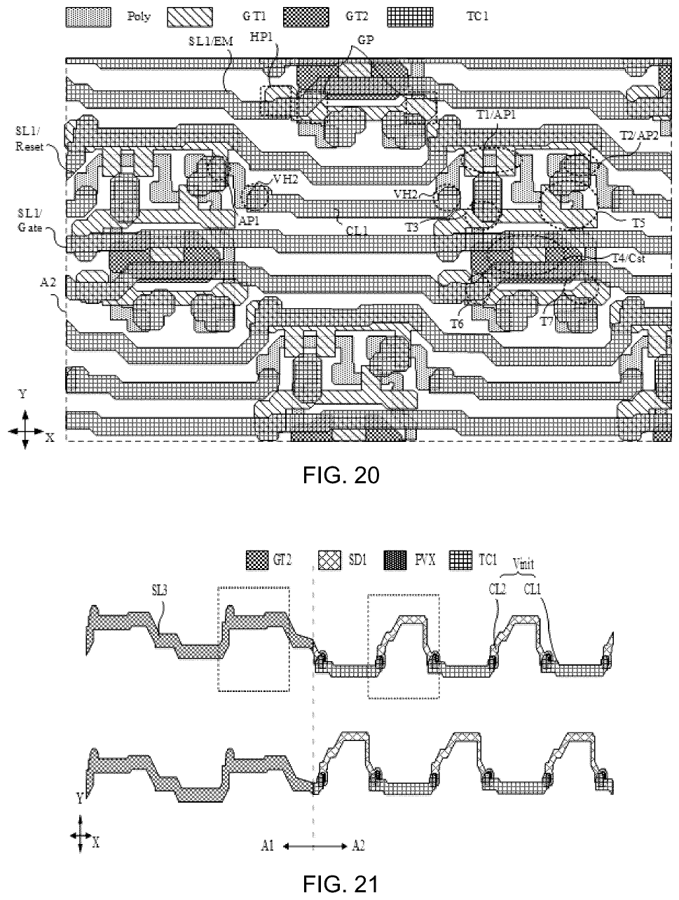

In some embodiments, as shown in FIGS. 13 and 20, the first pixel circuit 31 includes a plurality of gate patterns GP, and the plurality of gate patterns GP are arranged in a plurality of columns in the first direction X and arranged in a plurality of rows in the second direction Y.

For example, the plurality of gate patterns GP are arranged in an array.

For example, a first pixel circuit 31 includes a plurality of transistors, and each transistor has at least one gate pattern GP.

For example, as shown in FIG. 20, a same row of gate patterns GP includes at least two gate patterns GP, and the at least two gate patterns GP are electrically connected to a same first-type signal line SL1.

For example, gate patterns GP of at least two transistors located in a same row are also located in a same row. When at least two transistors are turned on or off under control of a same electrical signal, gate patterns GP of the at least two transistors may be connected to a same signal line, e.g., a same first-type signal line SL1.

For example, a same row of gate patterns GP includes two gate patterns GP, the two gate patterns GP may be electrically connected to each other, and the two gate patterns GP are electrically connected to a same first-type signal line SL1.

As another example, a same row of gate patterns GP includes four gate patterns, and the four gate patterns GP may be electrically connected to each other. The four gate patterns GP are electrically connected to a same first-type signal line SL1.

In this way, multiple gate patterns GP in the same row may be electrically connected to the first-type signal line SL1, thereby reducing the number of first via holes VH1, reducing the diffraction phenomenon of the external light at the first via holes VH1 during the process of the external light entering the optical component 50, and in turn avoiding affecting the function of the optical component 50.

In some embodiments, as shown in FIGS. 14 and 20, at least two gate patterns GP are electrically connected to the first-type signal line SL1 through a same first via hole connection portion HP1.

For example, two gate patterns GP located in the same row may be electrically connected to each other, and one of the two gate patterns GP may be electrically connected to the first via hole connection portion HP1, so that the two gate patterns GP are electrically connected to the same first-type signal line SL1 through one first via hole connection portion HP1, which may reduce the number of first via holes VH1. As a result, it may be possible to reduce the diffraction phenomenon of the external light at the first via holes VH1 during the process of the external light entering the optical component 50, and in turn avoid affecting the function of the optical component 50.

As another example, four gate patterns GP located in the same row may be electrically connected to each other, and one of the four gate patterns GP may be electrically connected to the first via hole connection portion HP1, so that the four gate patterns GP are electrically connected to the same first-type signal line SL1 through one first via hole connection portion HP1, which may reduce the number of first via holes VH1. As a result, it may be possible to reduce the diffraction phenomenon of the external light at the first via holes VH1 during the process of the external light entering the optical component 50, and in turn avoid affecting the function of the optical component 50.

In some embodiments, as shown in FIG. 14, the at least two gate patterns GP are of a one-piece structure; and/or the at least two gate patterns GP and the first via hole connection portion HP1 electrically connected to the at least two gate patterns GP are of a one-piece structure.

For example, two gate patterns GP located in the same row are of a one-piece structure.

As another example, four gate patterns GP located in the same row are of a one-piece structure.

For example, two gate patterns GP located in the same row and the first via hole connection portion HP1 electrically connected to the two gate patterns GP are of a one-piece structure.

As another example, four gate patterns GP located in the same row and the first via hole connection portion HP1 electrically connected to the four gate patterns GP are of a one-piece structure.

The above “one-piece structure” means that two patterns connected to each other are arranged in the same layer, and the two patterns are continuous and not separated. Therefore, it may be possible to simplify the structure and manufacturing process of the first pixel circuit 31 and the display panel 10.

In some embodiments, as shown in FIGS. 18 and 20, the first-type signal lines SL1 include at least one of the gate lines Gate, the reset signal lines Reset, or the enable signal lines EM.

For example, the first-type signal lines SL1 include the gate lines Gate. The gate patterns GP may be the gate pattern of the compensation transistor T5 and the gate pattern of the switching transistor T3.

As another example, the first-type signal lines SL1 include the reset signal lines Reset. The gate patterns GP may be the gate pattern of the first reset transistor T1 and the gate pattern of the second reset transistor T2.

As another example, the first-type signal lines SL1 include the enable signal lines EM. The gate patterns GP may be the gate pattern of the first light-emitting control transistor T6 and the gate pattern of the second light-emitting control transistor T7.

As another example, the first-type signal lines SL1 include the gate lines Gate and the reset signal lines Reset.

As another example, the first-type signal lines SL1 include the gate lines Gate and the enable signal lines EM.

As another example, the first-type signal lines SL1 include the reset signal lines Reset and the enable signal lines EM.

As another example, the first-type signal lines SL1 include the gate lines Gate, the reset signal lines Reset and the enable signal lines EM.

In this way, at least one of the gate line Gate, the reset signal line Reset or the enable signal line EM may be electrically connected to a row of first pixel circuits 31 through a first via hole VH1, so that the number of via holes in the secondary display region A2 is reduced, which mitigates the diffraction phenomenon during the process of the external light entering the optical component 50 and avoids the photographic diffraction phenomenon of the optical component 50 to a certain extent. In addition, the number of the first via holes VH1 is reduced, which may increase the gap between two adjacent first pixel circuits 31 in the secondary display region A2. That is, a region originally used to form the first via hole VH1 may be used as a region for the external light to enter and pass through, which means that an area of the light-transmitting region is increased. Thus, the light-transmitting area in the secondary display region A2 is increased, the light transmittance of the secondary display region A2 is increased, and the light collection amount of the optical component 50 is guaranteed.

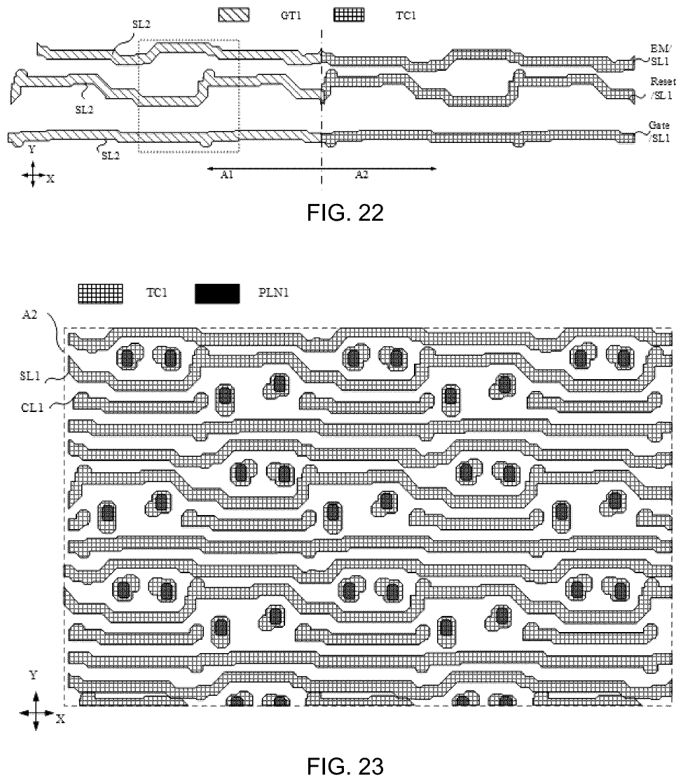

In some embodiments, as shown in FIG. 22, the first gate conductive layer GT1 further includes second-type signal lines SL2 located in the primary display region A1. The second-type signal lines SL2 extend in the first direction X, and are electrically connected to at least some second pixel circuits 32 among the plurality of second pixel circuits (the dotted box in FIG. 22 indicates a region where the second pixel circuit 32 is located).

For example, the second-type signal line SL2 is electrically connected to a row of second pixel circuits 32 among the plurality of second pixel circuits 32.

In some examples, the first-type signal line SL1 and the second-type signal line SL2 that transmit the same electrical signal are electrically connected to each other; and first pixel circuits 31 corresponding to the first-type signal line SL1 and second pixel circuits 32 corresponding to the second-type signal line SL2 are located in the same row.

For example, an electrical signal transmitted by the second-type signal line SL2 to the corresponding second pixel circuits 32 in the same row may be a scan signal, a reset signal or an enable signal.

In some examples, the second-type signal line SL2 transmitting the scan signal is electrically connected to the first-type signal line SL1 transmitting the scan signal. Furthermore, the second pixel circuits 32 corresponding to the second-type signal line SL2 and the first pixel circuits 31 corresponding to the first-type signal line SL1 are located in the same row. Thus, an electrical signal may be input to one of the first-type signal line SL1 and the second-type signal line SL2, and the first-type signal line SL1 and the second-type signal line SL2 transmit the same electrical signal to the same row of pixel circuits 30. As a result, the design of the display panel 10 may be simplified.

It will be understood that FIG. 22 only illustrates three second-type signal lines SL2 in the first gate conductive layer GT1 and three first-type signal lines SL1 in the first light-transmitting conductive layer TC1. The shape of the second-type signal line SL2 in FIG. 22 is only for illustration. The shape of the second-type signal line SL2 varies, which will not be limited in some embodiments of the present disclosure.

In some embodiments, as shown in FIGS. 12 and 20, the first pixel circuit 31 further includes a first active pattern AP1 and a second active pattern AP2 located in the semiconductor layer Poly and arranged at intervals in the first direction X.

It will be understood that the semiconductor layer Poly is located between the substrate 20 and the first gate conductive layer GT1.

For example, the first active pattern AP1 and the second active pattern AP2 have a gap therebetween, and they are not electrically connected.

In some examples, as shown in FIGS. 18 to 20 and 23, the first light-transmitting conductive layer TC1 further includes first connection lines CL1; and in the first direction X, a first connection line CL1 is located between two adjacent first pixel circuits 31.

For example, the first connection line CL1 extends in the first direction X.

In some examples, the first active pattern AP1 of one of the two adjacent first pixel circuits 31 is electrically connected to an end of the first connection line CL1 through a second via hole VH2. The second active pattern AP2 of another one of the two adjacent first pixel circuits 31 is electrically connected to another end of the first connection line CL1 through another second via hole VH2.

In some embodiments, as shown in FIGS. 16 to 17, the first source-drain conductive layer SD1 includes second connection lines CL2 located in the secondary display region A2. As shown in FIG. 19, in the first direction X, a second connection line CL2 is located between two adjacent first connection lines CL1, and connects the two adjacent first connection lines CL1.

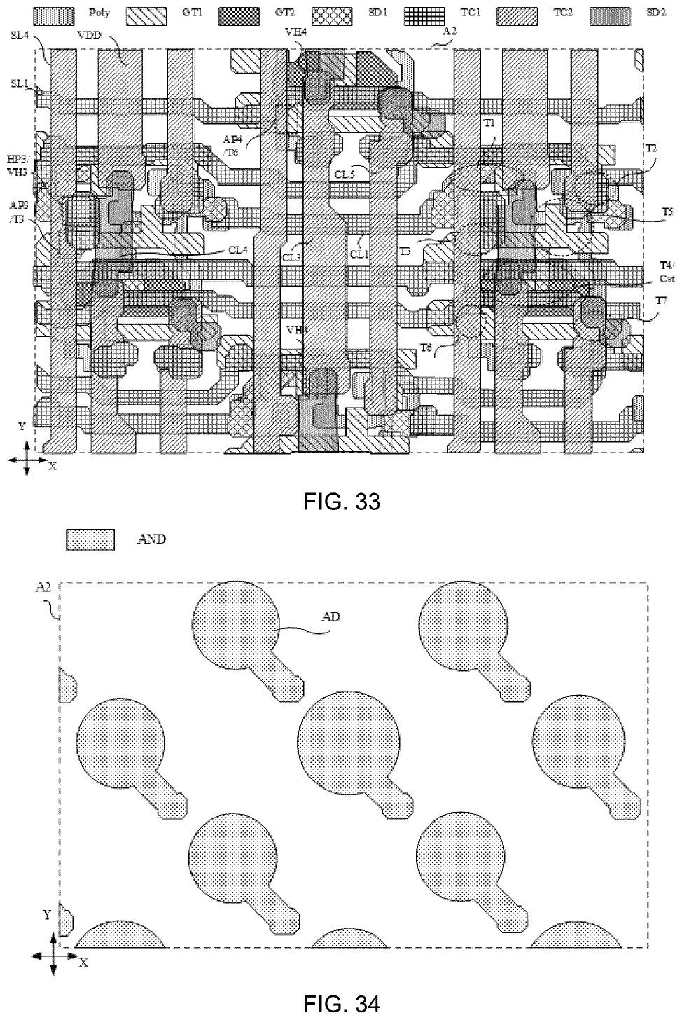

As shown in FIG. 33, the first source-drain conductive layer SD1 is located between the second gate conductive layer GT2 and the first light-transmitting conductive layer TC1.

For example, the second connection lines CL2 substantially extend in the first direction X.

For example, as shown in FIG. 19, the first connection line CL1 may be connected to the second connection line CL2 through via hole(s) VH located in the passivation layer PVX.

In this way, two adjacent first connection lines CL1 may be connected together, and multiple first connection lines CL1 connected to a row of first pixel circuits 31 may be connected to each other through second connection lines CL2, thereby facilitating the signal on the first connection line CL1 being transmitted to a corresponding row of first pixel circuits 31, which may simplify the design of the display panel 10 and avoid separately transmitting electrical signals to all first connection lines CL1 in the same row of first connection lines.

In some embodiments, as shown in FIG. 19, in the first direction X, a plurality of first connection lines CL1 and a plurality of second connection lines CL2 are alternately arranged, and are sequentially connected to constitute an initial signal line Vinit.

For example, the initial signal line Vinit extends in the first direction X.

For example, the initial signal line Vinit is electrically connected to a row of first pixel circuits 31, and transmits an initial signal to the row of first pixel circuits 31.

For example, when a plurality of first connection lines CL1 and a plurality of second connection lines CL2 are sequentially connected to constitute an initial signal line Vinit, the above-mentioned first active pattern AP1 may be the active pattern of the first reset transistor T1, and the above-mentioned second active pattern AP2 may be the active pattern of the second reset transistor T2. The initial signal line Vinit transmits the initial signal to the first reset transistor T1 through the first active pattern AP1, and transmits the initial signal to the second reset transistor T2 through the second active pattern AP2.

In some embodiments, as shown in FIG. 21, the second gate conductive layer GT2 includes: a plurality of third-type signal lines SL3 located in the primary display region A1. The plurality of third-type signal lines SL3 extend in the first direction X; and the third-type signal line SL3 is electrically connected to second pixel circuits 32 in the same row.

For example, the second gate conductive layer GT2 is located between the first gate conductive layer GT1 and the first light-transmitting conductive layer TC1.

For example, the third-type signal line SL3 is electrically connected to the initial signal line Vinit, and first pixel circuits 31 corresponding to the initial signal line Vinit and second pixel circuits 32 corresponding to the third-type signal line SL3 are located in the same row (the dotted boxes in FIG. 21 indicate the positions of the first pixel circuit and the second pixel circuit).

For example, the third-type signal line SL3 is used to transmit an initial signal to a row of second pixel circuits 32. The third-type signal line SL3 is electrically connected to the initial signal line Vinit, so that initial signals received by the pixel circuits 30 in the same row in the display panel 10 are the same. Therefore, light-emitting devices 40 corresponding to the pixel circuits 30 in the same row are in the same initial state before light emitting, which enables the display panel 10 to display images normally.

It will be understood that FIG. 21 only illustrates two third-type signal lines SL3 in the second gate conductive layer GT2 and two initial signal lines Vinit. The shape of the third-type signal line SL3 in FIG. 21 is only for illustration. The shape of the third-type signal line SL3 varies, which will not be limited in the present disclosure.

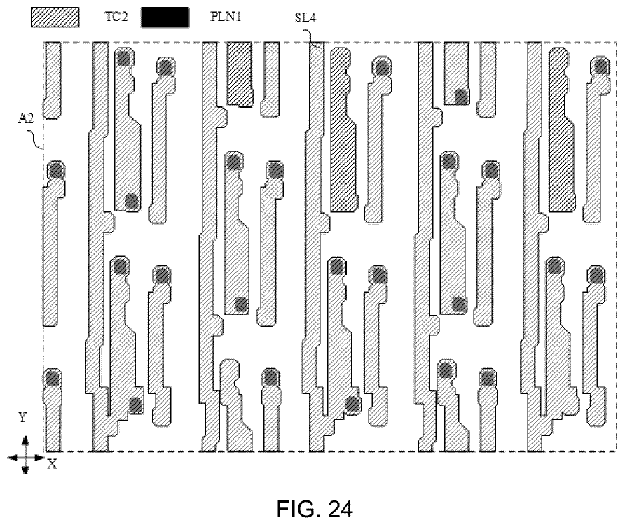

In some embodiments, as shown in FIGS. 24, 25 and 27, the display panel 10 further includes: a second light-transmitting conductive layer TC2 located on the first light-transmitting conductive layer TC1 and located in the secondary display region A2, and the second light-transmitting conductive layer TC2 includes: fourth-type signal lines SL4 extending in the second direction Y.

It will be understood that, as shown in FIGS. 23 and 24, a first planarization layer PLN1 is provided between the second light-transmitting conductive layer TC2 and the first light-transmitting conductive layer TC1.

For example, a material of the second light-transmitting conductive layer TC2 has both light-transmitting and conductive properties.

For example, the first light-transmitting conductive layer TC1 and the second light-transmitting conductive layer TC2 may be made of the same material.

For example, the second light-transmitting conductive layer TC1 may be made of ITO.

In some examples, as shown in FIGS. 12 and 29, the first pixel circuit 31 further includes a third active pattern AP3 located in the semiconductor layer Poly. A third active pattern AP3 of each of first pixel circuits 31 in the same column is electrically connected to a fourth-type signal line SL4 through a third via hole VH3. The third via hole VH3 is located on a side of the first pixel circuit 31 in the second direction Y.

In some embodiments, each first pixel circuit 31 is electrically connected to the fourth-type signal line SL4 through a third via hole VH3. It will be understood that the relative position relationship between the third via hole VH3 and the corresponding first pixel circuit 31 varies, which may be set according to actual needs, which will not be limited in the present disclosure.

For example, in the same column of first pixel circuits 31, third via holes VH3 corresponding to different first pixel circuits 31 may each be located on a different side of a respective first pixel circuit 31 in the second direction Y.

As another example, in the same column of first pixel circuits 31, third via holes VH3 corresponding to different first pixel circuits 31 are each located on a same side of a respective first pixel circuit 31 in the second direction Y.

In this way, the arrangement of the third via holes VH3 in the display panel may be more regular, thereby reducing the difficulty of manufacturing the display panel.

For example, a single fourth-type signal line SL4 is electrically connected to a single column of first pixel circuits 31.

In some examples, the fourth-type signal line SL4 is located in the same layer in the secondary display region A2 and is a continuous line, and an orthographic projection of the fourth-type signal line SL4 on the substrate overlaps with an orthographic projection of at least one first pixel circuit 31 among the plurality of first pixel circuits 31 on the substrate.

For example, the orthographic projection of the fourth-type signal line SL4 on the substrate overlaps with an orthographic projection of one first pixel circuit 31 on the substrate.

As another example, the orthographic projection of the fourth-type signal line SL4 on the substrate overlaps with orthographic projections of multiple first pixel circuits 31 on the substrate.

For example, as shown in FIG. 29, a portion of a fourth-type signal line SL4 is located in a gap between two adjacent first pixel circuits 31 in a column of first pixel circuits 31, and another portion of the fourth-type signal line SL4 covers a corresponding first pixel circuit 31.

For example, the fourth-type signal line SL4 is formed by a strip pattern that is integral and unbroken and substantially in the first direction. The entire fourth-type signal line SL4 is located in the same layer in the secondary display region, and is located in the second light-transmitting conductive layer TC2. Thus, it may simplify the process of manufacturing the display panel.

For example, as shown in FIG. 29, the third via hole VH3 refers to a via hole penetrating through film layers (for example, the first planarization layer PLN1, the passivation layer PVX, the interlayer dielectric layer ILD, the second insulating layer, the first insulating layer, etc.) between the second light-transmitting conductive layer TC2 and the semiconductor layer Poly in order to realize the electrical connection between the third active pattern AP3 and the fourth type signal line SL4. Due to the limitation of the process of forming via holes and the thicknesses of the film layers, the third via hole VH3 may be composed of a plurality of sub-holes sequentially connected in the Z direction. The sub-holes are substantially concentrically arranged, or the sub-holes are staggered with each other. The sub-holes are located in different film layers, and a conductive transfer block is formed in each sub-hole. The conductive transfer block extends to an upper surface of a film layer where a corresponding sub-hole is located (for example, the conductive transfer block may be formed by using the material of the first source-drain conductive layer), and each conductive transfer block passes through each sub-hole to realize the electrical connection between the third active pattern AP3 and the fourth type signal line SL4.

For example, an orthographic projection of a fourth type signal line SL4 on the substrate 20 partially overlaps with an orthographic projection of each first pixel circuit 31 in a corresponding column of first pixel circuits 31 on the substrate 20.

In some embodiments of the present disclosure, the second light-transmitting conductive layer TC2 is provided in the secondary display region A2; the second light-transmitting conductive layer TC2 includes fourth-type signal lines SL4; the fourth-type signal lines SL4 extend in the second direction Y; and the third active pattern AP3 of the first pixel circuit 31 in the same column in the secondary display region A2 is electrically connected to the fourth-type signal line SL4 through a third via hole VH3. Therefore, the number of fourth-type signal lines SL4 around or inside the region occupied by a single first pixel circuit 31 is small. Compared with the one implementation, the number of fourth-type signal lines SL4 around or inside the region occupied by each first pixel circuit 31 is reduced, so that the number of via holes in the secondary display region A2 is reduced, which mitigates the diffraction phenomenon during the process of the external light entering the optical component 50 and ameliorates the photographic diffraction phenomenon of the optical component 50 to a certain extent. In addition, the number of the fourth-type signal lines SL4 is reduced, which may increase the gap between two adjacent first pixel circuits 31 in the secondary display region A2. That is, the region originally used to form the third via hole VH3 may be used as a region for the external light to enter and pass through, i.e., the light-transmitting region. Thus, the light-transmitting area in the secondary display region A2 is increased, the light transmittance of the secondary display region A2 is increased, and the light collection amount of the optical component 50 is guaranteed.

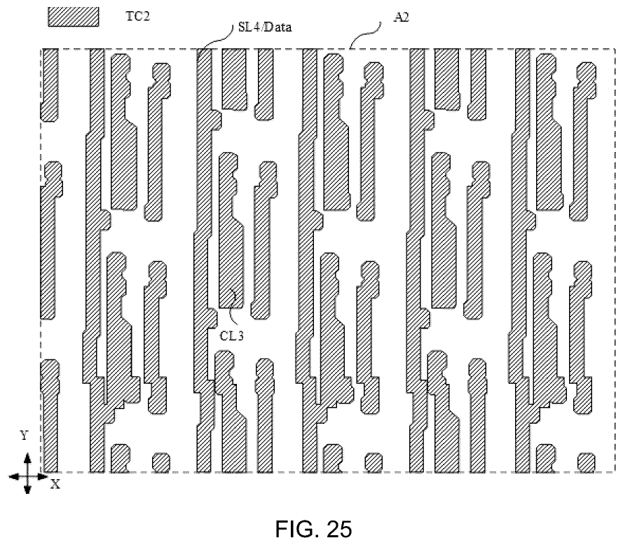

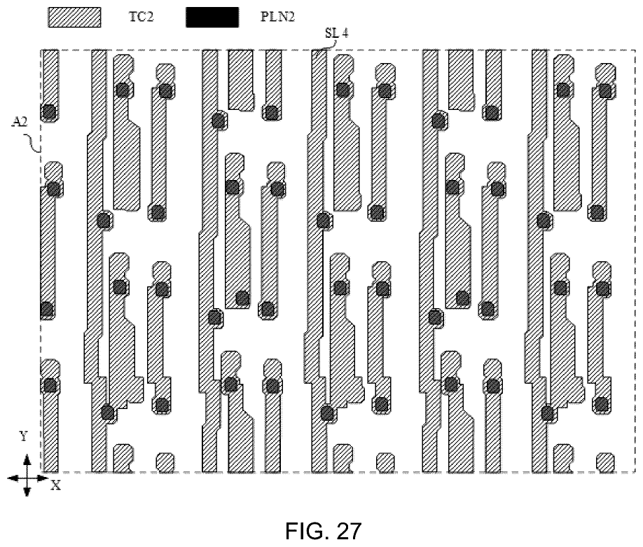

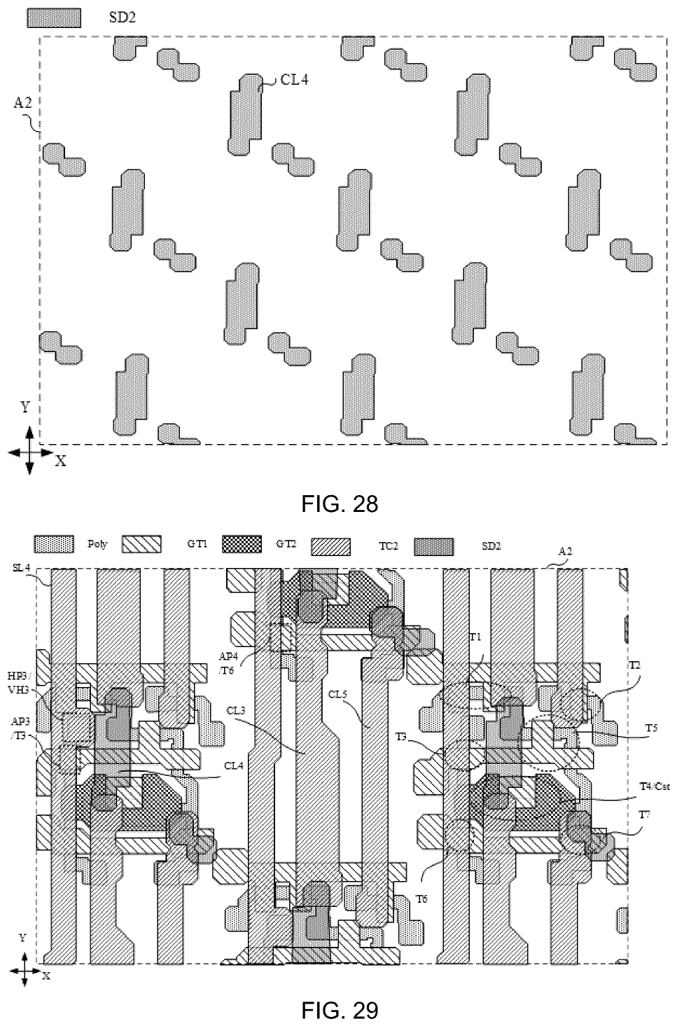

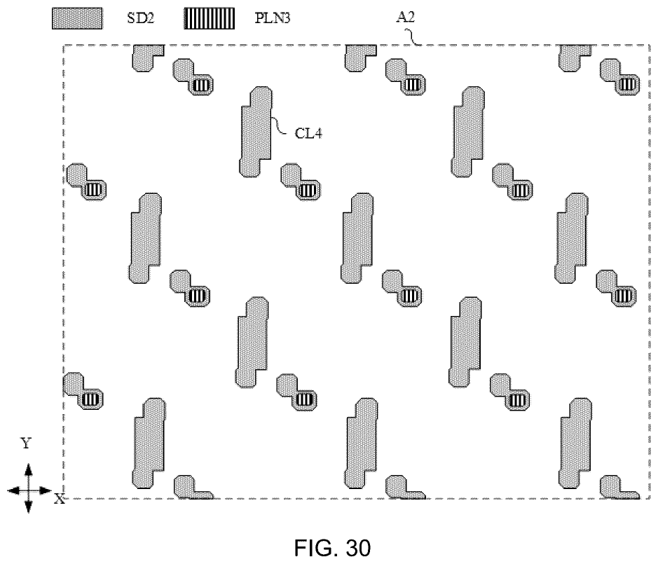

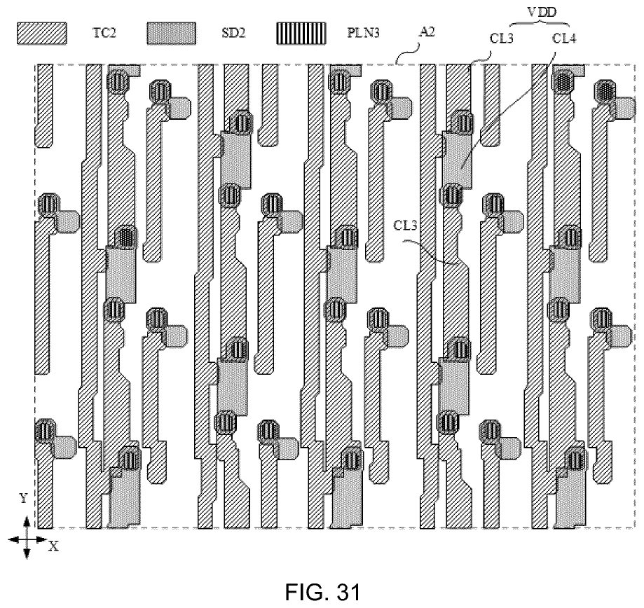

It will be understood that, FIG. 20 illustrates a top view of a structure where a semiconductor layer Poly, a first gate conductive layer GT1, a second gate conductive layer GT2 and a first light-transmitting conductive layer TC1 are sequentially stacked in a secondary display region A2. FIG. 23 illustrates a top view of a structure where a first light-transmitting conductive layer TC1 and a first planarization layer PLN1 are sequentially stacked in a secondary display region A2 (only positions of via holes in the first planarization layer PLN1 in the secondary display region A2 are illustrated in FIG. 23). FIG. 24 illustrates a top view of a structure where a first planarization layer PLN1 and a second light-transmitting conductive layer TC2 are sequentially stacked in a secondary display region A2 (only positions of via holes in the first planarization layer PLN1 in the secondary display region A2 are illustrated in FIG. 24). FIG. 25 illustrates a top view of a structure of a second light-transmitting conductive layer TC2 in a secondary display region A2. FIG. 27 illustrates a top view of a structure of a second light-transmitting conductive layer TC2 and a second planarization layer PLN2 are sequentially stacked in a secondary display region A2 (only positions of via holes in the second planarization layer PLN2 in the secondary display region A2 are illustrated in FIG. 27). FIG. 28 illustrates a top view of a structure of a second source-drain conductive layer SD2 in a secondary display region A2. FIG. 29 illustrates a top view of a structure where a semiconductor layer Poly, a first gate conductive layer GT1, a second gate conductive layer GT2, a second light-transmitting conductive layer TC2 and a second source-drain conductive layer SD2 are sequentially stacked in a secondary display region A2. FIG. 30 illustrates a top view of a structure of a second source-drain conductive layer SD2 and a third planarization layer PLN3 are sequentially stacked in a secondary display region A2 (only positions of via holes in the third planarization layer PLN3 in the secondary display region A2 are illustrated in FIG. 30). FIG. 31 illustrates a top view of a structure where a second light-transmitting conductive layer TC2, a second source-drain conductive layer SD2 and a third planarization layer PLN3 are sequentially stacked in a secondary display region A2 (only positions of via holes in the third planarization layer PLN3 in the secondary display region A2 are illustrated in FIG. 31). FIG. 33 illustrates a top view of a structure where a semiconductor layer Poly, a first gate conductive layer GT1, a second gate conductive layer GT2, a first source-drain conductive layer SD1, a first light-transmitting conductive layer TC1, a second light-transmitting conductive layer TC2 and a second source-drain conductive layer SD2 are sequentially stacked in a secondary display region A2. FIG. 34 illustrates a top view of a structure of an anode layer AND in a secondary display region A2.

The first planarization layer PLN1, the second planarization layer PLN2 and the third planarization layer PLN3 may be made of the same material.

For example, the first planarization layer PLN1 may be made of an insulating material, such as silicon oxide, silicon nitride or silicon oxynitride.

For example, film layers stacked in sequence on a side of the first light-transmitting conductive layer TC1 away from the substrate may include the first planarization layer PLN1, the second light-transmitting conductive layer TC2, the second planarization layer PLN2, the second source-drain conductive layer SD2, the third planarization layer PLN3 and the anode layer AND.

Of course, there may be other film layers between the substrate and the anode layer AND, which may be set according to actual needs, which will not be limited in the present disclosure.

In some embodiments, as shown in FIGS. 12 and 29, the semiconductor layer Poly includes a third via hole connection portion HP3 connected to the third active pattern AP3, the third via hole VH3 exposes the third via hole connection portion HP3, and the third active pattern AP3 is electrically connected to the fourth-type signal line SL4 through the third via hole connection portion HP3.

The third via hole connection portion HP3 is located on a side outside the region occupied by the first pixel circuit 31, or is located within the region occupied by the first pixel circuit 31.

For example, the third via hole VH3 may expose a portion of the third via hole connection portion HP3.

For example, the third active pattern AP3 and the third via hole connection portion HP3 are arranged in the same layer and made of the same material.

For example, the third via hole connection portion HP3 is located in a surrounding region outside the region occupied by the first pixel circuit 31 where the third active pattern AP3 electrically connected to the third via hole connection portion HP3 is located.

As another example, an orthographic projection, on the substrate 20, of the third via hole connection portion HP3 is located within an orthographic projection, on the substrate 20, of the first pixel circuit 31 where the third active pattern AP3 electrically connected to the third via hole connection portion HP3 is located. Thus, it may be possible to reduce an area occupied by the third via hole VH3 of the light-transmitting region in the secondary display region A2, and in turn make the area of the light-transmitting region of the secondary display region A2 larger. As a result, it may be possible to increase the light transmittance of the secondary display region A2, increase the light collection amount of the optical component 50, and ensure the normal operation of the optical component 50.

For example, the fourth-type signal line SL4 covers the third via hole VH3.

In this way, the third active pattern AP3 is electrically connected to the fourth-type signal line SL4 through a third via hole connection portion HP3, which may avoid a limitation of a relative position of an orthographic projection of the third active pattern AP3 on the substrate, and in turn avoid that the orthographic projection of the fourth-type signal line SL4 on the substrate needs to partially overlap with the orthographic projection of the third active pattern AP3 on the substrate, or avoid that the orthographic projection of the fourth-type signal line SL4 on the substrate needs to be located around the orthographic projection of the third active pattern AP3 on the substrate, so as to facilitate the electrical connection between the third active pattern AP3 and the fourth-type signal line SL4.

Moreover, when there are a large number of fourth-type signal lines SL4 in the second light-transmitting conductive layer TC2, it may be convenient to arrange the relative positions of the plurality of fourth-type signal lines SL4 in the second light-transmitting conductive layer TC2. Since the third active pattern AP3 is electrically connected to the fourth-type signal line SL4 through a third via hole connection portion HP3, it may be possible to avoid interference between electrical signals on adjacent fourth-type signal lines SL4 due to a small spacing between adjacent fourth-type signal lines SL4. As a result, it may be possible to improve the accuracy of the electrical signals transmitted by the fourth-type signal lines SL4, and in turn improve the display quality of images displayed by the display panel 10.

In some embodiments, as shown in FIG. 25, the fourth-type signal lines SL4 include data signal lines Data.

For example, the data signal line Data is electrically connected to a column of first pixel circuits 31, and transmits a data signal to the column of first pixel circuits 31.

For example, as shown in FIG. 33, when the fourth-type signal lines SL4 include the data signal lines Data, the third active pattern AP3 may be the active pattern of the switching transistor T3 in the first pixel circuit 31.

In this way, the data signal line Data may be electrically connected to a column of first pixel circuits 31 through a third via hole VH3, so that the number of via holes in the secondary display region A2 is reduced, which mitigates the diffraction phenomenon during the process of the external light entering the optical component 50 and avoids the photographic diffraction phenomenon of the optical component 50 to a certain extent. In addition, the number of the third via holes VH3 is reduced, which may increase the gap between two adjacent first pixel circuits 31 in the secondary display region A2. That is, a region originally used to form the third via hole VH3 may be used as a region for the external light to enter and pass through, which means that an area of the light-transmitting region is increased. Thus, the light-transmitting area in the secondary display region A2 is increased, the light transmittance of the secondary display region A2 is increased, and the light collection amount of the optical component 50 is guaranteed.

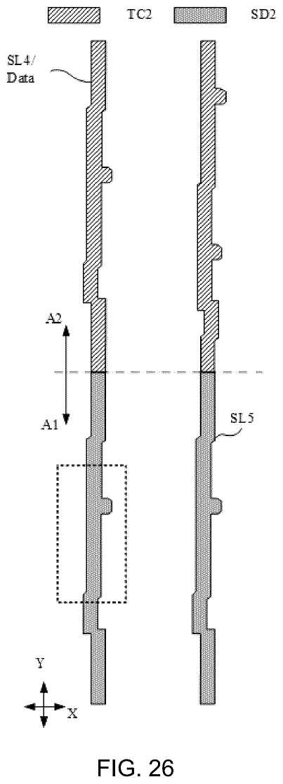

In some embodiments, as shown in FIG. 26, the second source-drain conductive layer SD2 includes: a plurality of fifth-type signal lines SL5 located in the primary display region A1. The plurality of fifth-type signal lines SL5 extend in the second direction Y; and a fifth-type signal line SL5 is electrically connected to second pixel circuits 32 in the same column.

For example, the plurality of fifth-type signal lines SL5 are arranged at intervals.

For example, the fifth-type signal line SL5 is electrically connected to a column of second pixel circuits 32 (the dotted box in FIG. 26 indicates a region where the second pixel circuit is located). In the case where the fourth-type signal lines SL4 include the data signal lines, the fifth-type signal line SL5 transmits a data signal to a column of second pixel circuits 32 electrically connected thereto.

In some examples, the fifth-type signal line SL5 is electrically connected to the fourth-type signal line SL4, and first pixel circuits 31 corresponding to the fourth-type signal line SL4 and second pixel circuits 32 corresponding to the fifth-type signal line SL5 are located in the same column. Thus, an electrical signal may be input to one of the fourth-type signal line SL4 and the fifth-type signal line SL5, and the fourth-type signal line SL4 and the fifth-type signal line SL5 may transmit the same electrical signal to the same column of pixel circuits 30. As a result, the design of the display panel 10 may be simplified.

It will be understood that FIG. 26 only illustrates two fifth-type signal lines SL5 in the second source-drain conductive layer SD2 and two fourth-type signal lines SL4 in the second light-transmitting conductive layer TC2. The shape of the fifth-type signal line SL5 in FIG. 26 is only for illustration. The shape of the fifth-type signal line SL5 varies, which will not be limited in the present disclosure.

In some embodiments, as shown in FIG. 14, the first pixel circuit 31 includes a capacitor pattern CP located in the second gate conductive layer GT2.

In some examples, as shown in FIG. 12, the first pixel circuit 31 further includes a fourth active pattern AP4 located in the semiconductor layer Poly.

In some examples, as shown in FIGS. 25, 29 and 33, the second light-transmitting conductive layer TC2 further includes: third connection lines CL3; and in the second direction Y, a third connection line CL3 is located between two adjacent first pixel circuits 31.

For example, the fourth active pattern AP4 of one of two adjacent first pixel circuits 31 is electrically connected to an end of the third connection line CL3 through a fourth via hole VH4. The capacitor pattern CP of another one of the two adjacent first pixel circuits 31 is electrically connected to another end of the third connection line CL3 through another fourth via hole VH4.

For example, the third connection lines CL3 extend in the second direction Y.

A fourth active pattern AP4 of a first pixel circuit 31 and a capacitor pattern CP of another first pixel circuit 31 adjacent to the first pixel circuit 31 in the second direction Y are connected together through a third connection line CL3. Since the third connection line CL3 is made of a light-transmitting material, a light transmittance of a gap between two adjacent first pixel circuits 31 in the second direction Y may be high. Therefore, the light transmittance of the secondary display region A2 is high, and the optical component 50 may collect sufficient light, which improves the photographic quality. In addition, in this way, the fourth active pattern AP4 and the capacitor pattern CP in the first pixel circuit 31 may all be electrically connected to the third connection line CL3, so that the fourth active pattern AP4 and the capacitor pattern CP each receive the electrical signal on the third connection line CL3. Thus, the fourth active pattern AP4 and the capacitor pattern CP receive the same electrical signal from the third connection line CL3.

In some embodiments, as shown in FIGS. 28 to 31, the second source-drain conductive layer SD2 includes fourth connection lines CL4 located in the secondary display region A2. In the second direction Y, a fourth connection line CL4 is located between two adjacent third connection lines CL3 and connects the two adjacent third connection lines CL3.

For example, the fourth connection lines CL4 extend in the second direction Y.

For example, the third connection line CL3 may be connected to the fourth connection line CL4 through a via hole.

In this way, two adjacent third connection lines CL3 may be connected together, and multiple third connection lines CL3 connected to a column of first pixel circuits 31 may be connected to each other through fourth connection lines CL4, thereby facilitating the signal on the third connection line CL3 being transmitted to a corresponding column of first pixel circuits 31, which may simplify the design of the display panel 10 and avoid separately transmitting electrical signals to all third connection lines CL3 in the same column of first connection lines.

In some embodiments, as shown in FIG. 31, in the second direction Y, a plurality of third connection lines CL3 and a plurality of fourth connection lines CL4 are alternately arranged and sequentially connected, and are configured to transmit a first voltage signal.

For example, the plurality of third connection lines CL3 and the plurality of fourth connection lines CL4 are sequentially connected to constitute a first voltage signal line VDD.

For example, the first voltage signal line VDD extends in the second direction Y. The first voltage signal line VDD is electrically connected to a column of first pixel circuits 31 through fourth active patterns AP4 and capacitor patterns CP, and transmits the first voltage signal to the column of first pixel circuits 31.

As shown in FIG. 33, in the case where a plurality of third connection lines CL3 and a plurality of fourth connection lines CL4 are alternately arranged in the second direction Y to constitute a first voltage signal line VDD, the above-mentioned fourth active pattern AP4 may be the active pattern of the first light-emitting control transistor T6, and the capacitor pattern CP may be the first electrode plate of the above-mentioned storage capacitor Cst.

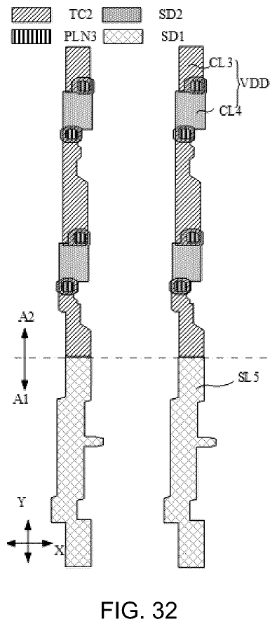

In some embodiments, as shown in FIG. 32, the first source-drain conductive layer SD1 further includes: a plurality of fifth-type signal lines SL5 located in the primary display region A1. The plurality of fifth-type signal lines SL5 extend in the second direction Y. A fifth-type signal line SL5 is electrically connected to second pixel circuits 32 located in the same column.

In some examples, the fifth-type signal line SL5 is connected to the first voltage signal line VDD, and first pixel circuits 31 corresponding to the first voltage signal line VDD and second pixel circuits 32 corresponding to the fifth-type signal line SL5 are located in the same column.

For example, the fifth-type signal line SL5 is used to transmit a first voltage signal to a column of second pixel circuits 32.

For example, the fifth-type signal line SL5 is used to transmit the first voltage signal to a column of second pixel circuits 32. The fifth-type signal line SL5 is electrically connected to the first voltage signal line VDD, so that first voltage signals received by the pixel circuits 30 in the same column of the display panel 10 are the same. Therefore, light-emitting devices 40 corresponding to the pixel circuits 30 in the same column receive same driving voltages, which enables the display panel 10 to display images normally.

As shown in FIG. 29, the second light-transmitting conductive layer TC2 further includes fifth connection lines CL5. A fifth connection line CL5 is located between two adjacent first pixel circuits 31 in the second direction Y, and is used to connect the second electrode of the second reset transistor T2 of one of the two first pixel circuits 31 and the second electrode of the second light-emitting control transistor T7 of another one of the two first pixel circuits 31.

For example, as shown in FIG. 34, the anode layer AND located in the secondary display region A2 includes a plurality of anodes AD.

For example, the plurality of anodes AD are electrically connected to the corresponding plurality of first pixel circuits 31. The anode AD is electrically connected to the second electrode of the second reset transistor T2 in the first pixel circuit 31, and the anode AD is further electrically connected to the second electrode of the second light-emitting control transistor T7.

Of course, the anode layer is also located in the primary display region. A plurality of anodes located in the primary display region are electrically connected to corresponding second pixel circuits. The anode is electrically connected to the second electrode of the second reset transistor T2 in the second pixel circuit, and the anode is further electrically connected to the second electrode of the second light-emitting control transistor T7.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display panel, comprising a primary display region and a secondary display region, the primary display region surrounding at least a part of the secondary display region, a light transmittance of the primary display region being less than a light transmittance of the secondary display region;
the display panel comprising a plurality of first pixel circuits located in the secondary display region, wherein the plurality of first pixel circuits are arranged in a plurality of rows and a plurality of columns, first pixel circuits in each row are arranged in a first direction, and first pixel circuits in each column are arranged in a second direction, the first direction and the second direction intersecting;
the display panel comprising:
a substrate;
a first conductive layer located on the substrate, wherein the plurality of first pixel circuits include conductive patterns located in the first conductive layer; and
a first signal line layer located on a side of the first conductive layer away from the substrate and located in the secondary display region, wherein the first signal line layer includes first-type signal lines extending in the first direction;
wherein a conductive pattern of each first pixel circuit located in a same row in the first direction is electrically connected to a first-type signal line through a first via hole, and the first via hole is located on a side of the first pixel circuit in the first direction.

2. The display panel according to claim 1, wherein each of the first pixel circuits is electrically connected to a first-type signal line through a first via hole; and first via holes corresponding to different first pixel circuits are each located on a same side of a respective first pixel circuit.

3. The display panel according to claim 1, wherein the first conductive layer is a first gate conductive layer, the conductive pattern is a gate pattern, and the first signal line layer is a first light-transmitting conductive layer.

4. The display panel according to claim 3, wherein the first gate conductive layer includes a first via hole connection portion electrically connected to the gate pattern; the first via hole exposes the first via hole connection portion; the gate pattern is electrically connected to the first-type signal line through the first via hole connection portion;
the first via hole connection portion is located on a side outside a region occupied by the first pixel circuit, or is located within the region occupied by the first pixel circuit.

5. The display panel according to claim 4, wherein the first pixel circuit includes a plurality of gate patterns; the plurality of gate patterns are arranged in a plurality of columns in the first direction, and are arranged in a plurality of rows in the second direction;
a same row of gate patterns includes at least two gate patterns; and the at least two gate patterns are electrically connected to a same first-type signal line through a same first via hole connection portion.

6. The display panel according to claim 5, wherein the at least two gate patterns are of a one-piece structure; and/or
the at least two gate patterns and the first via hole connection portion electrically connected to the at least two gate patterns are of a one-piece structure.

7. The display panel according to claim 1, wherein
the first-type signal lines include at least one of gate lines, reset signal lines, or enable signal lines.

8. The display panel according to claim 1, wherein the first-type signal line in the secondary display region is located in a same layer and is a continuous line; and an orthographic projection of the first-type signal line on the substrate overlaps with an orthographic projection of at least one first pixel circuit among the plurality of first pixel circuits on the substrate.

9. The display panel according to claim 1, further comprising a plurality of second pixel circuits located in the primary display region, wherein
the first conductive layer is a first gate conductive layer, and the first gate conductive layer further includes second-type signal lines located in the primary display region; the second-type signal lines extend in the first direction and are electrically connected to at least some second pixel circuits among the plurality of second pixel circuits;
a first-type signal line and a second-type signal line that transmit a same electrical signal are electrically connected to each other.

10. The display panel according to claim 1, further comprising: a semiconductor layer located on a side of the first conductive layer close to the substrate, and a second light-transmitting conductive layer that is located on a side of the first signal line layer away from the substrate and located in the secondary display region; wherein the second light-transmitting conductive layer includes: fourth-type signal lines extending in the second direction;
the first pixel circuit further includes a third active pattern located in the semiconductor layer;
a third active pattern of each first pixel circuit in a same column is electrically connected to a fourth-type signal line through a third via hole, and the third via hole is located on a side of the first pixel circuit in the second direction.

11. The display panel according to claim 10, wherein each of the first pixel circuits is electrically connected to a fourth-type signal line through a third via hole; and third via holes of different first pixel circuits are each located on a same side of a respective first pixel circuit.

12. The display panel according to claim 10, wherein the fourth-type signal line in the secondary display region is located in a same layer and is a continuous line; and an orthographic projection of the fourth-type signal line on the substrate overlaps with an orthographic projection of at least one first pixel circuit among the plurality of first pixel circuits on the substrate.

13. The display panel according to claim 10, wherein the semiconductor layer includes a third via hole connection portion electrically connected to the third active pattern; the third via hole exposes the third via hole connection portion; the third active pattern is electrically connected to the fourth-type signal line through the third via hole connection portion;
the third via hole connection portion is located on a side outside a region occupied by the first pixel circuit, or is located within the region occupied by the first pixel circuit.

14. The display panel according to claim 10, wherein the fourth-type signal lines include data signal lines.

15. The display panel according to claim 10, further comprising: a second source-drain conductive layer located on a side of the second light-transmitting conductive layer away from the substrate, and a plurality of second pixel circuits located in the primary display region, wherein
the second source-drain conductive layer includes a plurality of fifth-type signal lines located in the primary display region; the plurality of fifth-type signal lines extend in the second direction, and are electrically connected to at least some second pixel circuits among the plurality of second pixel circuits;
a fifth-type signal line is electrically connected to the fourth-type signal line.

16. The display panel according to claim 10, further comprising: a second gate conductive layer located on a side of a first gate conductive layer away from the substrate, wherein the first conductive layer is the first gate conductive layer; the first pixel circuit includes a capacitor pattern located in the second gate conductive layer;
the first pixel circuit further includes a fourth active pattern located in the semiconductor layer;
the second light-transmitting conductive layer further includes third connection lines; in the second direction, a third connection line is located between two adjacent first pixel circuits;
a fourth active pattern of one of the two adjacent first pixel circuits is electrically connected to an end of the third connection line through a fourth via hole;
a capacitor pattern of another one of the two adjacent first pixel circuits is electrically connected to another end of the third connection line through another fourth via hole.

17. The display panel according to claim 16, further comprising a second source-drain conductive layer located on a side of the second light-transmitting conductive layer away from the substrate, wherein the second source-drain conductive layer includes fourth connection lines located in the secondary display region;
in the second direction, a fourth connection line is located between two adjacent third connection lines and connects the two adjacent third connection lines.

18. The display panel according to claim 17, wherein in the second direction, a plurality of third connection lines and a plurality of fourth connection lines are alternately arranged and sequentially connected, and are configured to transmit a first voltage signal.

19. The display panel according to claim 1, further comprising a plurality of second pixel circuits located in the primary display region, wherein
within a unit area, an area occupied by the plurality of second pixel circuits is greater than an area occupied by the plurality of first pixel circuits.

20. A display apparatus, comprising the display panel according to claim 1; and
an optical component located on a non-light exit side of the display panel and located in the secondary display region of the display panel.
